(19) United States
(12) Patent Application Publication
(10) Pub. No.: US 2026/0334026 A1
(43) Pub. Date: Oct. 22, 2026

(54) DISPLAY DEVICE AND ELECTRONIC DEVICE INCLUDING THE SAME

(71) Applicant: SAMSUNG DISPLAY CO., LTD., YONGIN-SI, GYEONGGI-DO (KR)

(72) Inventor: Junwon Choi, YONGIN-SI (KR)

(21) Appl. No.: 19/577,444

(22) Filed: Mar. 25, 2026

(30) Foreign Application Priority Data
Apr. 21, 2025 (KR) 10-2025-0051904
Apr. 30, 2025 (KR) 10-2025-0057734
Sep. 12, 2025 (KR) 10-2025-0131131

(51) Int. Cl. H10K 59/131

(52) U.S. Cl. CPC H10K 59/131

(57) ABSTRACT

A display device includes a substrate including a display area with a first pixel having a first pixel electrode and a second pixel having a second pixel electrode, a first common voltage line having a plurality of pad portions extending in a first direction in the display area and spaced apart from each other in the first direction, a second common voltage line extending in a second direction crossing the first direction so as to overlap the second pixel electrode in the display area, and an insulating layer disposed between the first common voltage line and the second common voltage line. The second common voltage line is electrically connected to a corresponding pad portion of the plurality of pad portions of the first common voltage line through a first contact hole passing through the insulating layer in an area overlapping the corresponding pad portion.

### CROSS-REFERENCE TO RELATED APPLICATION(S)

This U.S. patent application claims priority under 35 U.S.C. § 119 to Korean Patent Application Nos. 10-2025-0051904, filed on Apr. 21, 2025, 10-2025-0057734, filed on Apr. 30, 2025, and 10-2025-0131131, filed on Sep. 12, 2025, in the Korean Intellectual Property Office, the disclosures of which are incorporated by reference in their entireties herein.

### 1. TECHNICAL FIELD

One or more embodiments relate to a display device and an electronic device including the same.

### 2. DISCUSSION OF RELATED ART

Display devices are used in a wide variety of electronic products, including mobile devices, notebook computers, monitors, televisions, wearable devices, and vehicle displays. Such display devices generally include a display panel having a display area in which a plurality of pixels are arranged to display an image, and a peripheral area in which driving circuitry and wiring for operating the display panel are disposed. As display resolution, panel size, and application diversity continue to increase, display panels are required to support increasingly dense pixel arrangements while maintaining stable electrical operation and uniform image quality across the display area.

In many display devices, each pixel operates based on a voltage difference between a driving voltage and a common voltage that serves as a reference potential. The common voltage is shared by a plurality of pixels and is supplied within the display panel so that the pixels may operate in a coordinated manner. Maintaining a stable common voltage across the display panel is important for consistent pixel operation and image quality.

As display panels increase in size, resolution, and operating current, the common voltage supplied within the display panel may be subject to local variation due to electrical resistance in the structures that convey the common voltage. In particular, differences in current loading and resistance within the display panel may cause the common voltage supplied to certain pixels to deviate from an intended voltage level. Such local deviations of the common voltage may change the effective operating voltage of the light-emitting elements, resulting in luminance non-uniformity, image quality degradation, and potential reliability concerns.

### SUMMARY

According to one or more embodiments, a display device includes a substrate including a display area with a first pixel having a first pixel electrode and a second pixel having a second pixel electrode, and a peripheral area disposed outside the display area, a first common voltage line having a plurality of pad portions extending in a first direction in the display area and spaced apart from each other in the first direction, a second common voltage line extending in a second direction crossing the first direction so as to overlap the second pixel electrode in the display area, and an insulating layer disposed between the first common voltage line and the second common voltage line, wherein the second common voltage line is electrically connected to a corresponding pad portion of the plurality of pad portions of the first common voltage line through a first contact hole passing through the insulating layer in an area overlapping the corresponding pad portion.

In an embodiment, the first contact hole may include a plurality of sub-contact holes spaced apart from each other.

In an embodiment, the first contact hole may have a first width along the first direction and a second width along the second direction, and the second width may be greater than the first width.

In an embodiment, the display apparatus may further include a first conductive pattern including a same material as a material of the first common voltage line, and a second conductive pattern including a same material as a material of the second common voltage line, wherein the at least one insulating layer may further include a second contact hole, and the first conductive pattern may be electrically connected to the second conductive pattern through a second contact hole in an area overlapping the second conductive pattern.

In an embodiment, an area of the first contact hole may be greater than an area of the second contact hole.

In an embodiment, an area of the first contact hole may be at least twice an area of the second contact hole.

In an embodiment, the first contact hole may include a plurality of sub-contact holes spaced apart from each other, and an area of one of the plurality of sub-contact holes may be equal to an area of the second contact hole.

In an embodiment, the first conductive pattern may include the first pixel electrode.

In an embodiment, the first pixel electrode and the first common voltage line may include a same material.

In an embodiment, the display apparatus may further include a third common voltage line extending in the second direction so as to overlap the first pixel electrode in the display area.

In an embodiment, the third common voltage line may include a same material as a material of the second common voltage line.

In an embodiment, the second pixel may be provided in plurality, and the plurality of pad portions may be alternately disposed with a plurality of second pixel electrodes disposed in the second direction.

In an embodiment, the second pixel may be configured to emit light having a blue wavelength.

In an embodiment, the display apparatus may further include a third pixel spaced apart from the first pixel in the second direction and having a third pixel electrode, wherein the first common voltage line may be disposed to pass between the first pixel electrode and the third pixel electrode.

In an embodiment, the plurality of pad portions may include a first pad portion and a second pad portion, and a first contact hole disposed to correspond to the first pad portion may be disposed in a central portion of the first pad portion.

In an embodiment, the second pad portion may include a protruding portion protruding in at least one direction, and a third contact hole disposed to correspond to the second pad portion may be disposed in the protruding portion.

In an embodiment, at least one insulating layer may be further disposed on the plurality of pad portions, and the at least one insulating layer may have an opening exposing a central portion of the second pad portion.

In an embodiment, the display device may further include, in a plan view, a fourth common voltage line at least partially overlapping an opening of an insulating layer disposed on the second pad portion and extending in the second direction, wherein the fourth common voltage line may include a first sub-common voltage line and a second sub-common voltage line, and the first sub-common voltage line and the second sub-common voltage line may have a connection portion where the first sub-common voltage line and the second sub-common voltage line are connected to each other in a partial area.

In an embodiment, the display device may further include a third common voltage line extending in the second direction, the first pixel may include a first light-emitting element including the first pixel electrode, and a first pixel circuit electrically connected to the first light-emitting element, wherein the first pixel circuit may include a thin-film transistor including a semiconductor layer, a gate electrode at least partially overlapping the semiconductor layer, and a first conductive layer disposed on the gate electrode and electrically connected to the semiconductor layer, and a second conductive layer disposed on the thin-film transistor, wherein each of the second common voltage line and the third common voltage line may include a same material as a material of the second conductive layer.

According to one or more embodiments, an electronic device includes a display device and a housing accommodating the display apparatus, wherein the display device includes a substrate including a display area with a first pixel having a first pixel electrode and a second pixel having a second pixel electrode, and a peripheral area disposed outside the display area, a first common voltage line having a plurality of pad portions extending in a first direction in the display area and spaced apart from each other in the first direction, a second common voltage line extending in a second direction crossing the first direction so as to overlap the second pixel electrode in the display area, and an insulating layer disposed between the first common voltage line and the second common voltage line, wherein the second common voltage line is electrically connected to a corresponding pad portion of the plurality of pad portions of the first common voltage line through a first contact hole passing through the insulating layer in an area overlapping the corresponding pad portion.

According to one or more embodiments, a display device includes a substrate having a display area including a plurality of pixels, first and second common voltage lines and an insulating layer disposed between the first common voltage line and the second common voltage line. Each pixel includes a pixel electrode configured to receive a common voltage. The first common voltage line extends in a first direction in the display area. The second common voltage line extends in a second direction crossing the first direction and is configured to supply the common voltage to the plurality of pixels. A plurality of contact holes pass through the insulating layer, the second common voltage line is electrically connected to the first common voltage line through the plurality of contact holes, and the plurality of contact holes are spaced apart from one another along the second direction.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a block diagram of an electronic device according to an embodiment;

FIGS. 2 to 4 are schematic diagrams of electronic devices according to various embodiments;

FIGS. 5A and 5B are schematic plan views of a display apparatus according to an embodiment;

FIG. 6 is a schematic plan view of a display apparatus according to an embodiment;

FIG. 7 is an equivalent circuit diagram schematically illustrating a pixel circuit and a light-emitting diode of a pixel according to an embodiment;

FIG. 8 is a plan view schematically illustrating a portion of a display area in a display apparatus, according to an embodiment;

FIG. 9 is a layout diagram schematically illustrating the structure of pixel circuits in pixels, according to an embodiment;

FIGS. 10 to 17 are layer-by-layer layout diagrams illustrating conductive patterns constituting the pixel circuit of FIG. 9;

FIG. 18 is a cross-sectional view schematically illustrating a cross-section including a pad portion according to an embodiment;

FIG. 19 is a schematic plan view of a pad portion according to an embodiment;

FIG. 20 is a cross-sectional view schematically illustrating a portion of a structure of a pixel circuit according to an embodiment;

FIG. 21 is a cross-sectional view schematically illustrating a portion of a display apparatus according to an embodiment;

FIG. 22 is a cross-sectional view schematically illustrating a portion of a display apparatus according to an embodiment; and

FIG. 23 is a cross-sectional view schematically illustrating a partial cross-section of FIG. 22.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

In the following embodiments, the terms “first,” “second,” etc. are not used merely to distinguish one element from another and are not intended to imply any particular order, priority, or importance. In addition, the singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements. It will be further understood that, when a layer, region, or element is referred to as being “on” another layer, region, or element, it may be directly or indirectly on the other layer, region, or element. That is, for example, intervening layers, regions, or elements may be present.

Also, sizes of elements in the drawings may be exaggerated or reduced for convenience of explanation. The drawings illustrate actual embodiments, but the relative sizes and thicknesses of components are not necessarily to scale, and one or more embodiments are not limited to the illustrated dimension.

The x-axis, the y-axis, and the z-axis are provided for convenience of description and are not limited to three-dimensional orthogonal coordinate system. For example, the x-axis, the y-axis, and the z-axis may be perpendicular to one another or may represent directions that are not perpendicular to one another.

When an embodiment is implemented in a different manner, a specific process sequence may differ from the sequence described herein. For example, two consecutively described processes may be performed substantially at the same time or in an order different from that described.

The display devices according to embodiments may be applied to various electronic devices. An electronic device according to an embodiment may include the display device described above and may further include, in addition to the display apparatus, modules or devices having other additional functions.

One or more embodiments relate to a display device in which a common voltage supplied to a plurality of pixels is distributed through conductive structures formed within a display area. In the display device, a first common voltage line extending in a first direction includes a plurality of pad portions, and a second common voltage line extending in a second direction overlaps the pad portions in a plan view. The common voltage lines may be disposed on different layers. The first and second common voltage lines are electrically connected through at least one contact hole formed in at least one insulating layer disposed between the common voltage lines. In some embodiments, the contact hole structure is configured to reduce contact resistance, for example, by increasing a number of contact holes or increasing an area of the contact hole, thereby suppressing local deviation of the common voltage and improving voltage uniformity, display quality, and reliability.

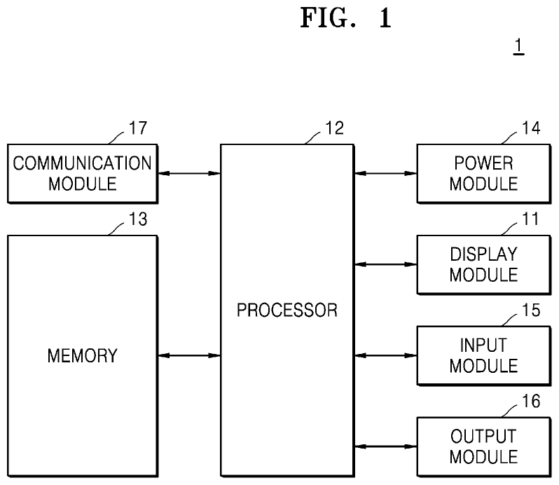

FIG. 1 is a block diagram of an electronic device 1 according to an embodiment.

Referring to FIG. 1, the electronic device 1 according to an embodiment may include a display module 11, a processor 12, a memory 13, and a power module 14 (e.g., a power supply). The electronic device 1 may further include an input module 15, a non-image output module 16, and/or a communication module 17.

The electronic device 1 may be configured to output various pieces of information in the form of an image through the display module 11. When the processor 12 executes an application stored in the memory 13, image information provided by the application may be provided to a user through the display module 11. The power module 14 may include a power supply module, such as a power adapter or a battery device, and a power conversion module configured to convert power supplied by the power supply module to generate power necessary for the operation of the electronic device 1. The input module 15 may be configured to provide input information to the processor 12 and/or the display module 11. The non-image output module 16 may be configured to receive, from the processor 12, information other than the image, for example, sound, haptics, and/or light emission, and provide the information to the user. The communication module 17 may be a module responsible for transmitting and receiving information between the electronic device 1 and an external device and may include a receiver and a transmitter.

At least one of the components of the electronic device 1 may be included in the display device according to the embodiments described above. Furthermore, some of the individual modules functionally included in a single module may be included in the display device, and others may be provided separately from the display device. For example, the display apparatus may include the display module 11, and the processor 12, the memory 13, and the power module 14 may be provided in the form of other devices within the electronic device 1 other than the display device.

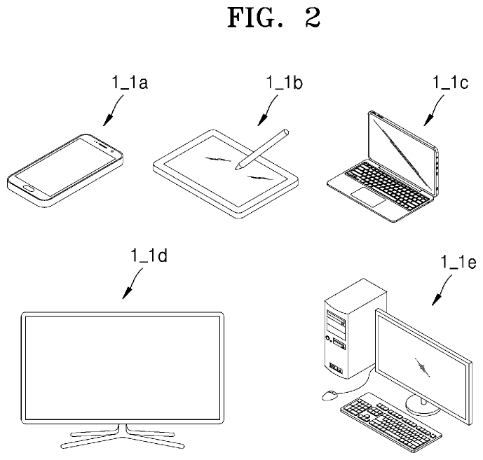

FIGS. 2 to 4 are schematic diagrams of electronic devices according to various embodiments. FIGS. 2 to 4 illustrate examples of various electronic devices to which the display apparatus according to embodiments is applied.

FIG. 2 illustrates examples of the electronic device, including a smartphone 1_1a, a tablet personal computer (PC) 1_1b, a laptop 1_1c, a television (TV) 1_1d, and a desk monitor 1_1e.

The smartphone 1_1a may include, in addition to the display module (see 11 of FIG. 1), a communication module and an input module such as a touch sensor. The smartphone 1_1a may be configured to process information received through the communication module or another input module and display the information on the display module of the display apparatus.

Similar to the smartphone 1_1a, the tablet PC 1_1b, the laptop 1_1c, the TV 1_1d, or the desk monitor 1_1e may include a display module and an input module and, in some cases, may further include a communication module.

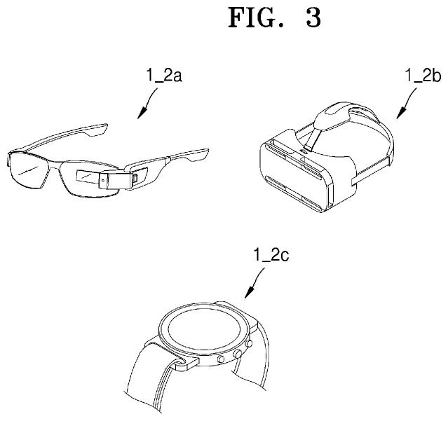

FIG. 3 illustrates examples in which an electronic device including a display module is applied to a wearable electronic device. The wearable electronic device may be smart glasses 1_2a, a head mounted display 1_2b, a smart watch 1_2c, etc.

Each of the smart glasses 1_2a and the head mounted display 1_2b may include a display module configured to display a display image and a reflector configured to provide the display image to the user's eyes by reflecting the displayed display image, and may provide a virtual reality or augmented reality screen to the user through the display module and the reflector.

The smart watch 1_2c may include a biometric sensor as an input device and may be configured to provide biometric information recognized by the biometric sensor to the user through the display module.

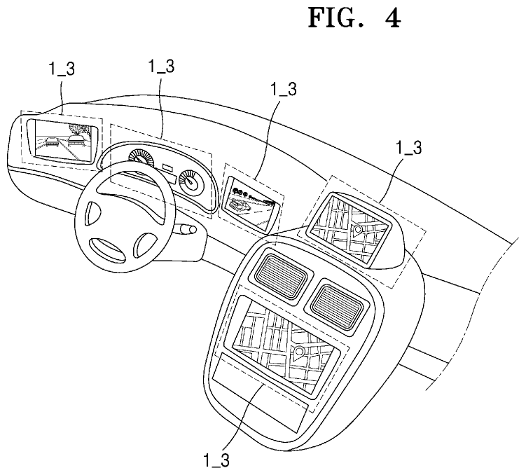

FIG. 4 illustrates an example in which an electronic device including a display module is applied to a vehicle. For example, an electronic device 1_3 may be applied to dashboards, center fascia, etc. of automobiles, or may be applied to center information displays (CIDs) on dashboards of automobiles or room mirror displays replacing side mirrors.

The electronic device to which the display device according to embodiments is applied may include screen display-oriented devices, such as billboards, electronic boards, or game consoles, and various home appliances that display information through display modules, such as refrigerators, washing machines, dryers, air conditioners, or robot vacuum cleaners. In addition, when the display module has a function of transmitting light, the display module may be applied to electronic devices, such as a smart window or a transparent display apparatus that displays a background and a display image together. The types of electronic devices according to embodiments are not limited to those described above, and application of various other electronic devices not described herein may also be possible.

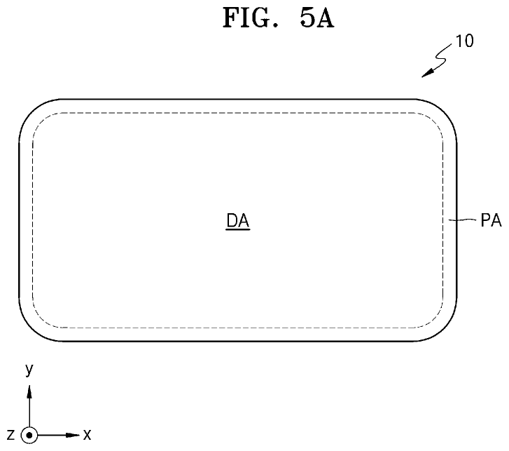

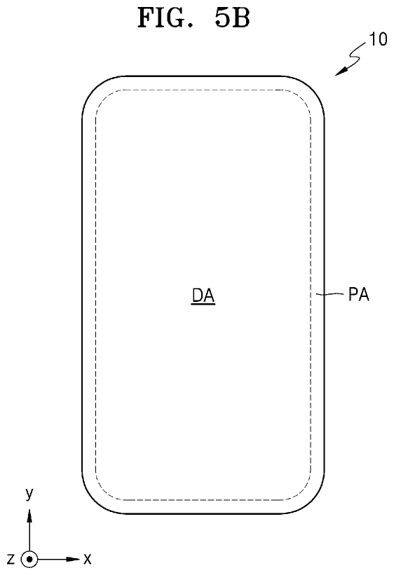

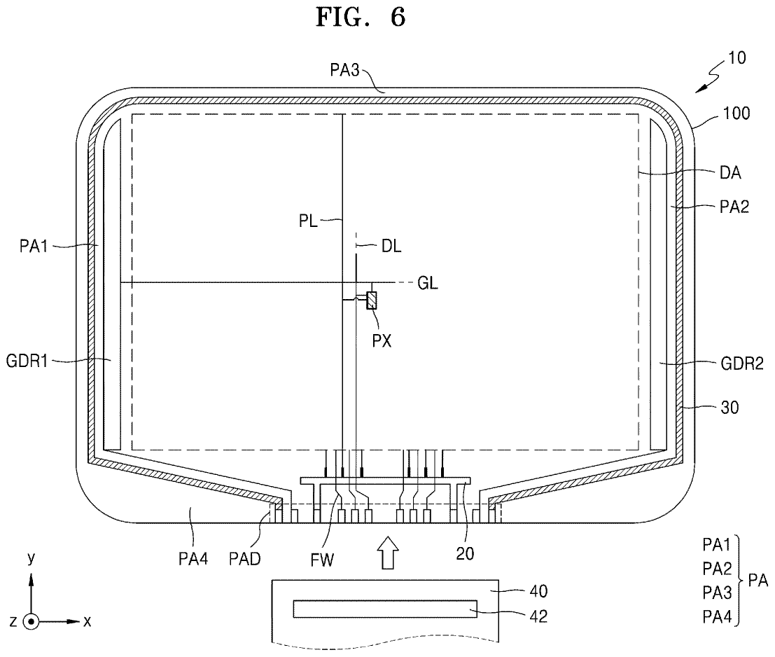

FIGS. 5A and 5B are schematic plan views of a display device 10 according to an embodiment. FIG. 6 is a schematic plan view of the display device 10 according to an embodiment.

The display device 10 described below may be included in the electronic device 1 described with reference to FIGS. 1 to 4. The display device 10 may include the display module 11 described with reference to FIG. 1.

Referring to FIGS. 5A and 5B, the display device 10 may include a display area DA, in which an image is displayed, and a peripheral area PA outside the display area DA. The display area DA may be completely surrounded by the peripheral area PA.

In a plan view, the display area DA may have a rectangular shape. In another embodiment, the display area DA may have a polygonal shape (e.g., a triangular shape, a pentagonal shape, or a hexagonal shape), a circular shape, an elliptical shape, or an irregular shape. The display area DA may have round edge corners. In an embodiment, the display area DA of the display apparatus 10 may have a shape in which the length thereof in a first direction (e.g., an x-axis direction) is greater than the length thereof in a second direction (e.g., a y-axis direction), as illustrated in FIG. 5A. In another embodiment, the display area DA of the display apparatus 10 may have a shape in which the length thereof in the second direction (e.g., the y-axis direction) is greater than the length thereof in the first direction (e.g., the x-axis direction), as illustrated in FIG. 5B.

Hereinafter, a case where the display area DA has the shape illustrated in FIG. 5A is described with reference to FIG. 6.

Referring to FIG. 6, the peripheral area PA may include a first peripheral area PA1, a second peripheral area PA2, a third peripheral area PA3, and a fourth peripheral area PA4. The first peripheral area PA1 and the second peripheral area PA2 may be respectively disposed at one side and another side (e.g., the left side and the right side) of the display area DA with the display area DA therebetween. The third peripheral area PA3 and the fourth peripheral area PA4 may be disposed to connect the first peripheral area PA1 to the second peripheral area PA2 with the display area DA therebetween. For example, the third peripheral area PA3 and the fourth peripheral area PA4 may be respectively disposed above and below the display area DA with the display area DA therebetween.

Various elements included in the display device 10 may be disposed on a substrate 100. A plurality of gate lines GL, a plurality of data lines DL, and a plurality of pixels PX connected thereto may be disposed in the display area DA.

The plurality of pixels PX may be disposed in various forms, such as a stripe arrangement, a pentile arrangement, a diamond arrangement, or a mosaic arrangement, and may implement an image. Each of the pixels PX may include an organic light-emitting diode (OLED) as a display element (i.e., a light-emitting diode), and the OLED may be connected to a pixel circuit. The pixel circuit may include a plurality of transistors and at least one capacitor. Each of the pixels PX may emit, for example, red light, green light, blue light, or white light from the OLED. Each of the pixels PX may be connected to a corresponding gate line among the plurality of gate lines GL and a corresponding data line among the plurality of data lines DL.

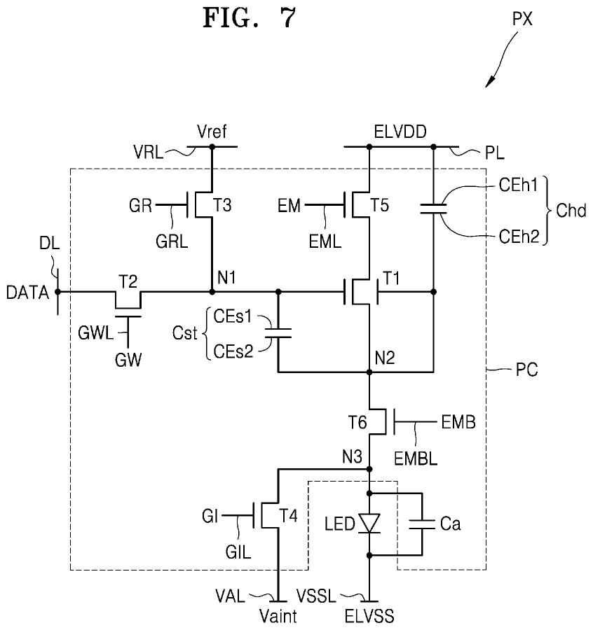

The gate lines GL may extend in the first direction (e.g., the x-axis direction) and may be connected to the pixels PX disposed in the same row. The gate lines GL may be configured to transmit gate signals to the pixels PX disposed in the same row. The data lines DL may extend in the second direction (e.g., the y-axis direction) and may be connected to the pixels PX disposed in the same column. The data lines DL may be configured to transmit data signals to the pixels PX disposed in the same column in synchronization with the gate signals, respectively. Each of the pixels PX may be connected to a driving voltage line PL and receive a driving voltage (see ELVDD of FIG. 7). The driving voltage line PL may extend in the second direction (e.g., the y-axis direction) and may be connected to the pixels PX disposed in the same column.

Although FIG. 6 illustrates an example in which the pixel PX is connected to one gate line GL, the embodiments are not limited thereto. For example, the pixel PX may be connected to one or more gate lines GL.

Each of the pixel circuits that drive the pixels PX may be electrically connected to peripheral circuits disposed in the peripheral area PA. A first gate driving circuit GDR1, a second gate driving circuit GDR2, a terminal portion PAD (e.g., a contact pad), a driving voltage supply line 20, and a common voltage supply line 30 may be disposed in the peripheral area PA.

The first gate driving circuit GDR1 may be disposed in the first peripheral area PA1. The first gate driving circuit GDR1 may be connected to the plurality of gate lines GL and may be configured to apply a gate signal to each of the pixel circuits that drive the pixels PX through the gate lines GL.

The second gate driving circuit GDR2 may be disposed in the second peripheral area PA2. That is, the second gate driving circuit GDR2 may be disposed on the opposite side of the first gate driving circuit GDR1 with respect to the display area DA and may be approximately parallel to the first gate driving circuit GDR1.

In an embodiment, the pixel circuits of the pixels PX of the display area DA may be electrically connected to the first gate driving circuit GDR1 and the second gate driving circuit GDR2. In another embodiment, some pixel circuits of the pixels PX of the display area DA may be electrically connected to the first gate driving circuit GDR1 and the remaining pixel circuits may be electrically connected to the second gate driving circuit GDR2. In another embodiment, the second gate driving circuit GDR2 may be omitted.

The terminal portion PAD may be disposed on one side of an edge of the substrate 100. The terminal portion PAD may be exposed by not being covered by an insulating layer and may be connected to a display circuit board 40. The display circuit board 40 may be, for example, a flexible printed circuit board (FPCB).

A display driver 42 (e.g., a driver circuit) may be disposed on the display circuit board 40. The display driver 42 may be disposed directly on the substrate 100 in a chip on glass (COG) or chip on plastic (COP) manner.

The display driver 42 may include a data driving circuit. The data driving circuit may be configured to generate a data signal. The generated data signal may be transmitted to the pixel circuits of the pixels PX through a fan-out line FW and a data line DL connected to the fan-out line FW. In some embodiments, the display driver 42 may include a power supply circuit, and the power supply circuit may be configured to supply a driving voltage ELVDD to the driving voltage supply line 20 and supply a common voltage ELVSS to the common voltage supply line 30. The driving voltage ELVDD may be applied to the pixel circuits of the pixels PX through the driving voltage line PL connected to the driving voltage supply line 20, and the common voltage ELVSS may be applied to an opposite electrode of the display element through the common voltage supply line 30. In some embodiments, the display driver 42 may include a controller, and the controller may be configured to generate a control signal to be transmitted to the first gate driving circuit GDR1, the second gate driving circuit GDR2, the data driving circuit, and the power supply circuit.

The driving voltage supply line 20 may extend along the first direction (e.g., the x-axis direction) on one side of the display area DA, for example, in the fourth peripheral area PA4, and may be connected to the terminal portion PAD.

The common voltage supply line 30 may be connected to the terminal portion PAD and may partially surround the display area DA. FIG. 6 illustrates that the common voltage supply line 30 is disposed in a loop shape with one side open and partially surrounds the display area DA in the first to third peripheral areas PA1, PA2, and PA3. In another embodiment, the common voltage supply line 30 may be disposed in the first to fourth peripheral areas PA1, PA2, PA3, and PA4 and completely surround the display area DA in a closed loop shape.

FIG. 7 is an equivalent circuit diagram schematically illustrating a pixel circuit and a light-emitting diode of a pixel according to an embodiment.

Referring to FIG. 7, a pixel PX may include a light-emitting diode LED and a pixel circuit PC connected to the light-emitting diode LED. The pixel PX may refer to a sub-pixel, and the pixel circuit PC may refer to a sub-pixel circuit. In some embodiments, the light-emitting diode LED may be, for example, an organic light-emitting diode (OLED).

The pixel circuit PC may include a plurality of transistors and a plurality of capacitors.

In an embodiment, the pixel circuit PC may include first to sixth transistors T1, T2, T3, T4, T5, and T6, a storage capacitor Cst, and a hold capacitor Chd. The first transistor T1, the second transistor T2, the third transistor T3, the fourth transistor T4, the fifth transistor T5, and the sixth transistor T6 may be respectively referred to as a driving transistor, a switching transistor, a compensation transistor, an initialization transistor, an operation control transistor, and an emission control transistor. A first terminal (a first electrode) of each of the first to sixth transistors T1, T2, T3, T4, T5, and T6 may be a source or a drain, and a second terminal (a second electrode) thereof may be a terminal that is different from the first terminal. For example, when the first terminal is a drain, the second terminal may be a source.

In an embodiment, each of the plurality of transistors included in the pixel circuit PC may be an n-channel metal-oxide semiconductor field effect transistor (MOSFET) (NMOS) including an oxide semiconductor layer. However, this is only an example, and the transistors of the disclosure are not limited thereto. In an embodiment, at least one of the first to sixth transistors T1, T2, T3, T4, T5, and T6 may be a p-channel MOSFET (PMOS) and the others may each be an NMOS. For example, the fifth transistor T5 may be a PMOS, and the first, second, third, fourth, and sixth transistors T1, T2, T3, T4, and T6 may each be an NMOS. Alternatively, the fifth transistor T5 and the sixth transistor T6 may each be a PMOS, and the first, second, third, and fourth transistors T1, T2, T3, and T4 may each be an NMOS. Alternatively, the first to sixth transistors T1, T2, T3, T4, T5, and T6 may be all an NMOS or a PMOS. The following description focuses on an embodiment in which the first to sixth transistors T1, T2, T3, T4, T5, and T6 are each an NMOS including an oxide semiconductor.

The pixel circuit PC may include a plurality of lines. In an embodiment, the pixel circuit PC may be electrically connected to a gate line GWL configured to transmit a gate signal GW, a reference gate line GRL configured to transmit a reference signal GR, a first emission control line EML configured to transmit a first emission control signal EM, an initialization gate line GIL configured to transmit an initialization signal GI, a second emission control line EMBL configured to transmit a second emission control signal EMB, and a data line DL configured to transmit a data signal DATA. The pixel circuit PC may be electrically connected to a driving voltage line PL configured to transmit a driving voltage ELVDD, a reference voltage line VRL configured to transmit a reference voltage Vref, and an initialization voltage line VAL configured to transmit an initialization voltage Vaint.

The first terminal (or the first electrode) and the second terminal (or the second electrode) of each of the first to sixth transistors T1, T2, T3, T4, T5, and T6 may be a source (or a source electrode) or a drain (or a drain electrode) depending on the voltages of the first terminal and the second terminal. For example, the first terminal may be a drain and the second terminal may be a source, or the first terminal may be a source and the second terminal may be a drain, depending on the voltages of the first terminal and the second terminal. Hereinafter, a node to which a first-1 gate electrode of the first transistor T1 is connected may be defined as a first node N1, and a node to which the second terminal of the first transistor T1 is connected may be defined as a second node N2.

The first transistor T1 may be connected to the driving voltage line PL and the light-emitting diode LED. The first transistor T1 may be connected between the fifth transistor T5 and the sixth transistor T6. The first transistor T1 may include a first gate electrode, the first terminal, and the second terminal connected to the second node N2. The first transistor T1 may include the first-1 gate electrode connected to the first node N1. The first transistor T1 may further include the first-2 gate electrode connected to the second terminal of the first transistor T1. The first-1 gate electrode and the first-2 gate electrode may be disposed to face each other in different layers. For example, the first-1 gate electrode and the first-2 gate electrode of the first transistor T1 may be opposite to each other with a semiconductor layer therebetween. In the disclosure, the first gate electrode of the first transistor T1 may refer to the first-1 gate electrode involved in turning on or off the first transistor T1.

The first-1 gate electrode of the first transistor T1 may be connected to the second terminal of the second transistor T2, the first terminal of the third transistor T3, and the storage capacitor Cst. The first-2 gate electrode of the first transistor T1 may be connected to the first terminal of the sixth transistor T6, the storage capacitor Cst, and the hold capacitor Chd. The first terminal of the first transistor T1 may be connected to the driving voltage line PL via the fifth transistor T5, and the second terminal of the first transistor T1 may be connected to a pixel electrode of the light-emitting diode LED via the sixth transistor T6. The first terminal of the first transistor T1 may be connected to the second terminal of the fifth transistor T5. The second terminal of the first transistor T1 may be connected to the first terminal of the sixth transistor T6, the storage capacitor Cst, and the hold capacitor Chd. The first transistor T1 may be configured to receive the data signal DATA according to the switching operation of the second transistor T2 and control the amount of driving current flowing to the light-emitting diode LED.

The second transistor T2 may be connected to the data line DL and the first gate electrode of the first transistor T1. The second transistor T2 may include a second gate electrode connected to the gate line GWL, the first terminal connected to the data line DL, and the second terminal connected to the first node N1. The second terminal of the second transistor T2 may be connected to the first gate electrode of the first transistor T1, the first terminal of the third transistor T3, and the storage capacitor Cst. The second transistor T2 may be configured to be turned on in response to the gate signal GW transmitted through the gate line GWL and electrically connect the data line DL to the first node N1 so that the data signal DATA transmitted through the data line DL is transmitted to the first node N1.

The third transistor T3 may be connected to the first gate electrode of the first transistor T1 and the reference voltage line VRL. The third transistor T3 may include a third gate electrode connected to the reference gate line GRL, the first terminal connected to the first node N1, and the second terminal connected to the reference voltage line VRL. The first terminal of the third transistor T3 may be connected to the first gate electrode of the first transistor T1, the second terminal of the second transistor T2, and the storage capacitor Cst. The third transistor T3 may be configured to be turned on in response to the reference signal GR transmitted through the reference gate line GRL and transmit, to the first node N1, the reference voltage Vref transmitted through the reference voltage line VRL.

The fourth transistor T4 may be connected to the sixth transistor T6 and the initialization voltage line VAL. The fourth transistor T4 may be connected between the light-emitting diode LED and the initialization voltage line VAL. The fourth transistor T4 may include a fourth gate electrode connected to the initialization gate line GIL, the first terminal connected to a third node N3, and the second terminal connected to the initialization voltage line VAL. The first terminal of the fourth transistor T4 may be connected to the second terminal of the sixth transistor T6 and the pixel electrode of the light-emitting diode LED. The fourth transistor T4 may be configured to be turned on in response to the initialization signal GI transmitted through the initialization gate line GIL and transmit, to the third node N3, the initialization voltage Vaint transmitted through the initialization voltage line VAL so that the pixel electrode (e.g., anode) of the light-emitting diode LED is initialized.

The fifth transistor T5 may be connected to the driving voltage line PL and the first transistor T1. The fifth transistor T5 may include a fifth gate electrode connected to the first emission control line EML, the first terminal connected to the driving voltage line PL, and the second terminal connected to the first terminal of the first transistor T1. The fifth transistor T5 may be configured to be turned on or off in response to the first emission control signal EM transmitted through the first emission control line EML.

The sixth transistor T6 may be connected to the first transistor T1 and the light-emitting diode LED. The sixth transistor T6 may be connected between the second node N2 and the third node N3. The sixth transistor T6 may include a sixth gate electrode connected to the second emission control line EMBL, the first terminal connected to the second node N2, and the second terminal connected to the third node N3. The first terminal of the sixth transistor T6 may be connected to the second terminal of the first transistor T1, the storage capacitor Cst, and the hold capacitor Chd. The second terminal of the sixth transistor T6 may be connected to the first terminal of the fourth transistor T4 and the pixel electrode of the light-emitting diode LED. The sixth transistor T6 may be configured to be turned on or off in response to the second emission control signal EMB transmitted through the second emission control line EMBL.

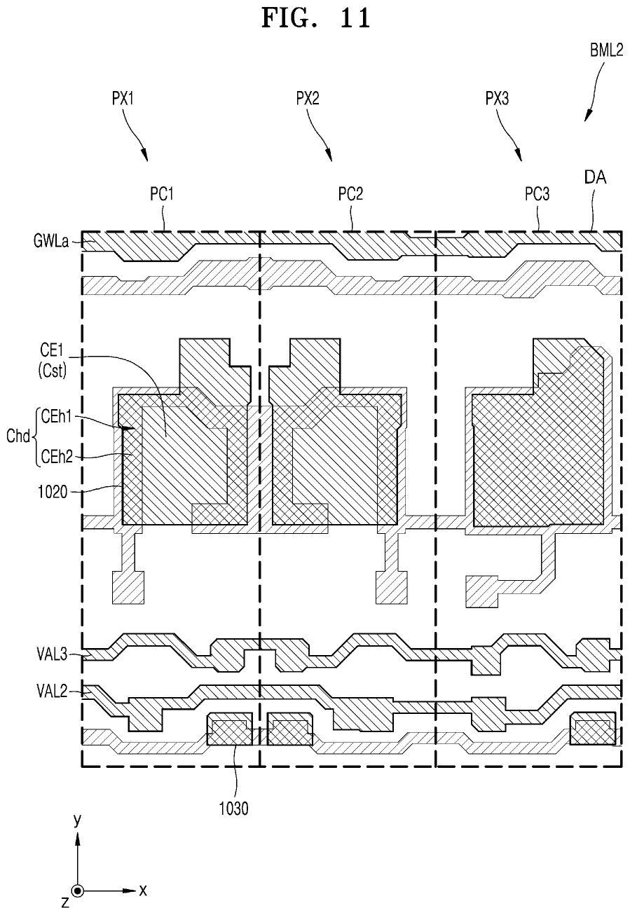

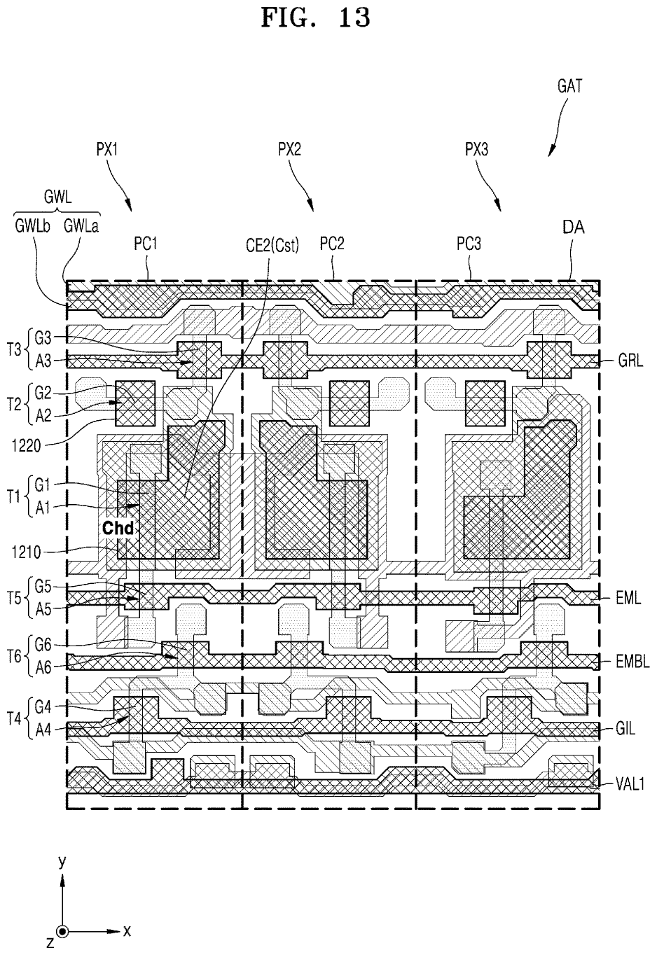

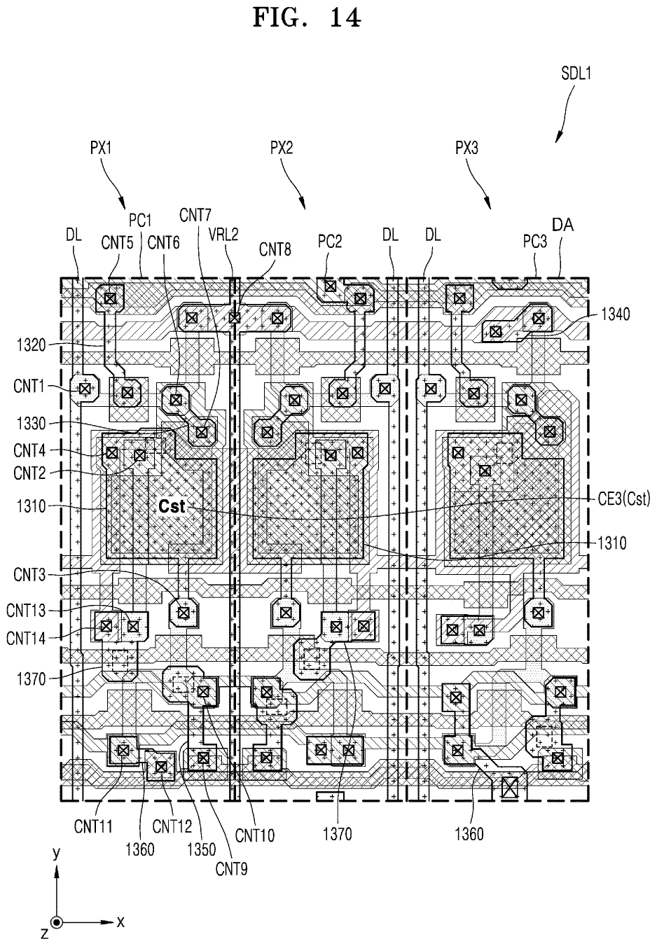

The storage capacitor Cst may be connected between the first gate electrode of the first transistor T1 and the second terminal of the first transistor T1. The storage capacitor Cst may include a first electrode CEs1 and a second electrode CEs2. The first electrode CEs1 of the storage capacitor Cst may correspond to an intermediate electrode (see CE2 of FIG. 13) to be described below, and the second electrode CEs2 of the storage capacitor Cst may correspond to a lower electrode (see CE1 of FIG. 11) and an upper electrode (see CE3 of FIG. 14) to be described below.

The first electrode CEs1 of the storage capacitor Cst may be connected to the first node N1, and the second electrode CEs2 of the storage capacitor Cst may be connected to the second node N2. The first electrode CEs1 of the storage capacitor Cst may be connected to the first gate electrode of the first transistor T1, the second terminal of the second transistor T2, and the first terminal of the third transistor T3. The second electrode CEs2 of the storage capacitor Cst may be connected to the second terminal and the first-2 gate electrode of the first transistor T1, a second hold electrode CEh2 of the hold capacitor Chd, and the first terminal of the sixth transistor T6. The storage capacitor Cst may be configured to store a voltage corresponding to the data signal DATA and a threshold voltage of the first transistor T1.

When the third transistor T3 and the fifth transistor T5 are turned on, the first transistor T1 may be turned on. When the voltage of the second terminal of the first transistor T1 drops to the difference (Vref−Vth1) between the reference voltage Vref and a threshold voltage (Vth1) of the first transistor T1, the first transistor T1 is turned off and the voltage corresponding to the threshold voltage (Vth1) of the first transistor T1 is stored in the storage capacitor Cst so that the threshold voltage (Vth1) of the first transistor T1 may be compensated for.

The hold capacitor Chd may be connected between the driving voltage line PL and the second node N2. The first hold electrode CEh1 of the hold capacitor Chd may be connected to the driving voltage line PL. The second hold electrode CEh2 of the storage capacitor Cst may be connected to the second terminal and the first-2 gate electrode of the first transistor T1, the second electrode CEs2 of the storage capacitor Cst, and the first terminal of the sixth transistor T6. The hold capacitor Chd may ensure that, even when a surrounding signal fluctuates, the voltage of the lower gate electrode of the first transistor T1 and the voltage of the second node N2 do not fluctuate and are constant.

The pixel circuit PC may further include an auxiliary capacitor Ca. The auxiliary capacitor Ca may be electrically connected to the sixth transistor T6, a sustain voltage line VSSL, and the pixel electrode of the light-emitting diode LED. The auxiliary capacitor Ca may store and maintain a voltage corresponding to the voltage difference between the pixel electrode of the light-emitting diode LED and the sustain voltage line VSSL, thereby preventing black luminance from increasing when the sixth transistor T6 is turned off.

The light-emitting diode LED may be electrically connected to the first transistor T1 through the sixth transistor T6. The light-emitting diode LED may include the pixel electrode (the anode) connected to the third node N3 and the opposite electrode (the cathode) facing the pixel electrode. The opposite electrode may be configured to receive a common voltage ELVSS. In an embodiment, the opposite electrode (the cathode) may be electrically connected to the sustain voltage line VSSL that extends into the display area and provides the common voltage ELVSS. Due to the turned-on fifth transistor T5 and the turned-on sixth transistor T6, the driving current output by the first transistor T1 may flow through the light-emitting diode LED. The light-emitting diode LED may emit light with a luminance corresponding to the amount of driving current.

Although FIG. 7 illustrates that the pixel circuit PC includes six transistors, the embodiments are not limited thereto. In another embodiment, the pixel circuit PC may include seven transistors. In another embodiment, the number of transistors in the pixel circuit PC may be 5 or less or 8 or more.

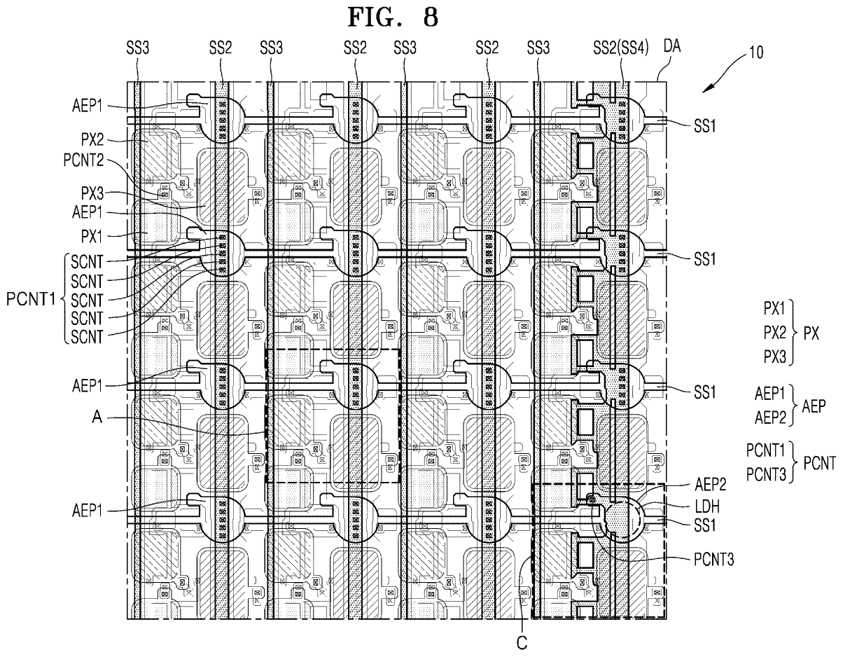

FIG. 8 is a plan view schematically illustrating a portion of a display area in the display device, according to an embodiment.

Referring to FIG. 8, a plurality of pixels PX may be disposed in a display area DA. Each of the plurality of pixels PX may include a pixel circuit PC and a light-emitting diode LED, as described above with reference to FIG. 7.

The plurality of pixels PX may include first to third pixels PX1, PX2, and PX3 disposed to form rows in the first direction (e.g., the x-axis direction) and columns in the second direction (e.g., the y-axis direction). Each of the first to third pixels PX1, PX2, and PX3 may be a sub-pixel, and a unit including the first to third pixels PX1, PX2, and PX3 may emit light as a single pixel PX. The first to third pixels PX1, PX2, and PX3 may emit pieces of light having different wavelengths. For example, the first pixel PX1 may be configured to emit first color light having a red wavelength, the second pixel PX2 may be configured to emit second color light having a green wavelength, and the third pixel PX3 may be configured to emit third color light having a blue wavelength.

In an embodiment, the first pixel PX1 and the second pixel PX2 may be disposed in the same column, and the third pixels PX3 may be disposed in another same column. The first pixel PX1 and the second pixel PX2 may be alternately disposed on a first column (e.g., a j^{th} column). The third pixel PX3 may be disposed in a second column (e.g., a (j+1)^{th} column) adjacent to the first column (e.g., the j^{th} column) in which the first pixel PX1 and the second pixel PX2 are disposed. In some embodiments, the first pixel PX1, the second pixel PX2, and the third pixel PX3 may be disposed in the same row. For example, the first pixel PX1 may be disposed in a first row (e.g., an i^{th} row), the second pixel PX2 may be disposed in a second row (e.g., an (i+1)^{th} row), and the third pixel PX3 may be disposed in a third row (e.g., an (i+2)^{th} row).

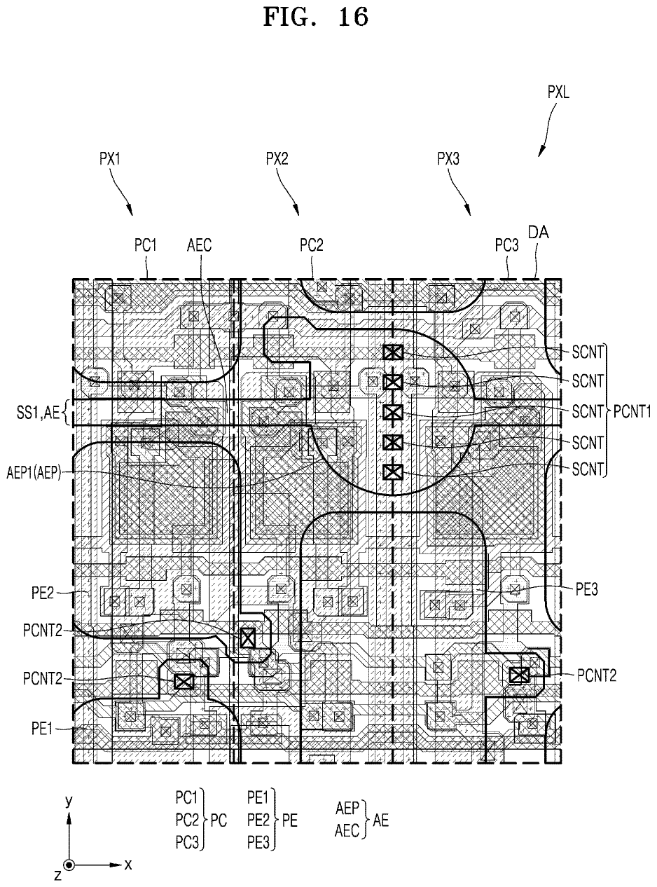

For reference, the expression that the first to third pixels PX1, PX2, and PX3 are disposed to form rows and columns as described above may mean the positions where first to third pixel electrodes (see PE1, PE2, and PE3 of FIG. 16) that substantially include the emission area are disposed.

For example, the areas where the first pixel PX1, the second pixel PX2, and the third pixel PX3 illustrated in FIG. 8 are disposed may be an area (hereinafter, a first pixel circuit area) where the first pixel circuit included in the first pixel PX1 is disposed, an area (hereinafter, a second pixel circuit area) where the second pixel circuit included in the second pixel PX2 is disposed, and an area (hereinafter, a third pixel circuit area) where the third pixel circuit included in the third pixel PX3 is disposed. However, the light-emitting diode included in the first pixel PX1 does not necessarily have to be disposed within the first pixel circuit area. For example, as illustrated in FIG. 8, the first pixel electrode (see PE1 of FIG. 16) electrically connected to the first pixel circuit included in the first pixel PX1 may be disposed across the first pixel circuit area and may also be disposed across an area indicated by the pixels disposed in the +y direction of the first pixel PX1. In some embodiments, the second pixel electrode (see PE2 of FIG. 16) electrically connected to the second pixel circuit included in the second pixel PX2 may be disposed in the first pixel circuit area while being disposed in the −y direction from the first pixel electrode PE1. In some embodiments, the third pixel electrode (see PE3 of FIG. 16) electrically connected to the third pixel circuit included in the third pixel PX3 may be disposed across the second pixel circuit area and the third pixel circuit area, and may also be disposed across areas indicated by the pixels disposed in the −y direction of the pixels. In this case, the first pixel electrodes (see PE1 of FIG. 16) and the second pixel electrodes (see PE2 of FIG. 16) may be alternately disposed in the first column (e.g., the j^{th} column), the third pixel electrodes PE3 may be disposed in the second column (e.g., the (j+1)^{th} column) adjacent to the first column (e.g., the j^{th} column), and the two columns may be alternately disposed along the first direction (e.g., the x-axis direction).

FIG. 8 illustrates a portion of a display area in which pixel units PX are arranged in a matrix. Each pixel unit PX is illustrated as including first to third pixels PX1, PX2, and PX3 for convenience of description. In one or more embodiments, a pixel unit PX may include a plurality of pixels arranged in a 4×4 matrix, in which at least one of the first to third pixels PX1, PX2, and PX3 is duplicated within the pixel unit. In the display device 10 according to an embodiment, a pixel layout structure including pixel units PX as described with reference to FIG. 8 may be repeatedly provided within the display area DA. In one or more embodiments, each pixel unit PX may include a plurality of pixels arranged in a 4×4 matrix, and the pixel layout structure illustrated in FIG. 8 is representative of such a repeated arrangement.

In an embodiment, one or more first common voltage lines SS1 extend in the first direction (e.g., the x-axis direction) in the display area DA, and one or more second common voltage lines SS2 and one or more third common voltage lines SS3 extend in the second direction (e.g., the y-axis direction) in the display area DA.

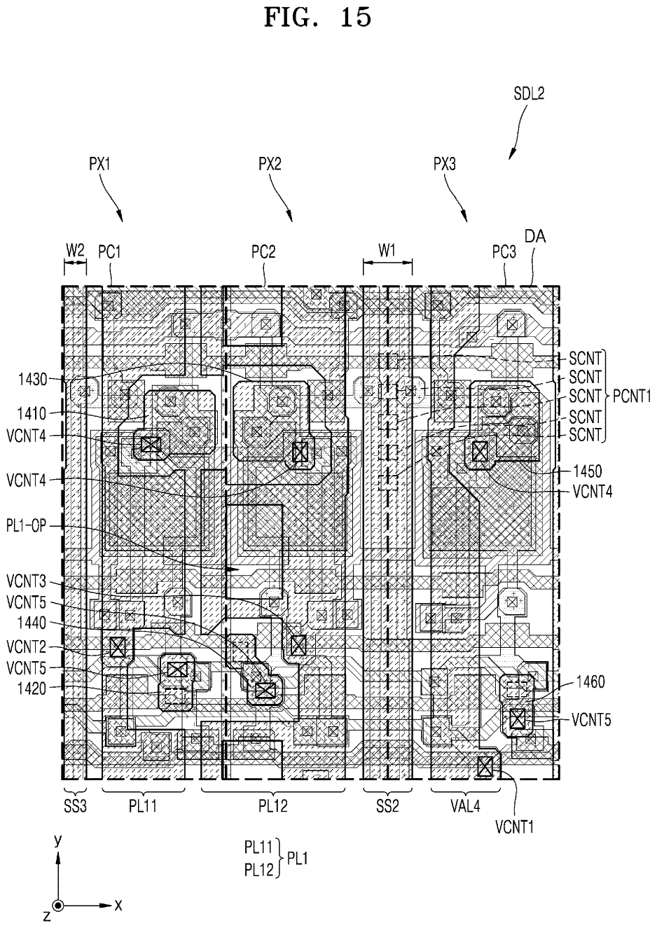

Each first common voltage line SS1 may extend in the first direction (e.g., the x-axis direction) across the entire display area DA. The first common voltage lines SS1 may be spaced apart from each other at certain intervals in the second direction (e.g., the y-axis direction) in the display area DA. Each first common voltage line SS1 may also be referred to as an auxiliary electrode AE to be described below with reference to FIG. 15, etc.

Each first common voltage line SS1 may include a plurality of pad portions AEP spaced apart from each other at certain intervals. Each of the plurality of pad portions AEP of a given first common voltage line SS1 may be disposed between the third pixel electrodes (see PE3 of FIG. 16) of the third pixel PX3 disposed in the second direction (e.g., the y-axis direction). For example, the pad portions AEP and the third pixel electrodes PE3 may be alternately disposed along the second direction (e.g., the y-axis direction).

The second common voltage lines SS2 and the third common voltage lines SS3 may extend in the second direction (e.g., the y-axis direction) across the entire display area DA. The second common voltage lines SS2 and the third common voltage lines SS3 may be disposed in different layers from the first common voltage lines SS1. In a cross-sectional view, the second common voltage lines SS2 and the third common voltage lines SS3 may be disposed below the first common voltage lines SS1. For example, a given first common voltage line SS1 may be disposed on the same layer as the first pixel electrode (see PE1 of FIG. 16), and a given second common voltage line SS2 and a given third common voltage line SS3 may be disposed below the first pixel electrode PE1. In an embodiment, in a cross-sectional view, a given second common voltage line SS2 and a given third common voltage line SS3 may be disposed between a given first common voltage line SS1 and the substrate 100.

A given second common voltage line SS2 may be disposed to overlap some of the pad portions AEP of the first common voltage lines SS1. For example, the given second common voltage line SS2 may be disposed along the second direction (e.g., the y-axis direction), and the overlapping pad portions AEP may be disposed above the given second common voltage line SS2. Accordingly, the given second common voltage line SS2 may be electrically connected to the overlapping pad portions AEP through contact holes PCNT to form a mesh structure as a whole in the display area DA. Such a structure may prevent or minimize a voltage drop (IR drop) in the common voltage supplied within the display device 10 even when its display area DA is excessively large.

The plurality of pad portions AEP may include a first pad portion AEP1 and a second pad portion AEP2. The first pad portion AEP1 and the second pad portion AEP2 may have substantially the same shape, but differ from each other in the position of the contact hole PCNT that is in contact with a given second common voltage line SS2.

For example, the first pad portion AEP1 may be connected to a given second common voltage line SS2 through a first contact hole PCNT1 defined in at least one insulating layer disposed between the first pad portion AEP1 and the second common voltage line SS2. The second pad portion AEP2 may be connected to a given second common voltage line SS2 through a third contact hole PCNT3 defined in at least one insulating layer disposed between the second pad portion AEP2 and the second common voltage line SS2. The first contact hole PCNT1 connecting a given second common voltage line SS2 to the first pad portion AEP1 may be disposed at the center of the first pad portion AEP1. The third contact hole PCNT3 connecting a given second common voltage line SS2 to the second pad portion AEP2 may be disposed on one side rather than at the center of the second pad portion AEP2.

The first pad portion AEP1 and the second pad portion AEP2 may have different contact hole arrangements because they serve different purposes in the display device. A plurality of first pad portions AEP1 may be provided along each first common voltage line SS1, and each first pad portion AEP1 may be configured to electrically connect a given first common voltage line SS1 to one of the second common voltage lines SS2 to distribute the common voltage ELVSS to a plurality of pixels PX. Accordingly, the first pad portions AEP1 may include a contact hole arrangement, such as a plurality of contact holes or an increased contact area, to reduce contact resistance. In contrast, the second pad portion AEP2 is used as a pad for a laser drilling process performed during manufacturing of the display device and is not configured as a primary current path for distribution of the common voltage ELVSS. Accordingly, in some embodiments, the second pad portion AEP2 may include a main pad region in which a laser drilling opening is formed and a protruding pad region in which a third contact hole PCNT3 is disposed, so that the third contact hole PCNT3 is offset from the laser drilling opening.

In FIG. 8, among a plurality of pad portions AEP disposed in a given region, the number of first pad portions AEP1 may be greater than the number of second pad portions AEP2. For example, in FIG. 8, one second pad portion AEP2 may be provided at a lower right end of the given region, while the remaining pad portions AEP may be the first pad portions AEP1. However, the number of second pad portions AEP2 among the plurality of pad portions AEP may be varied according to design requirements.

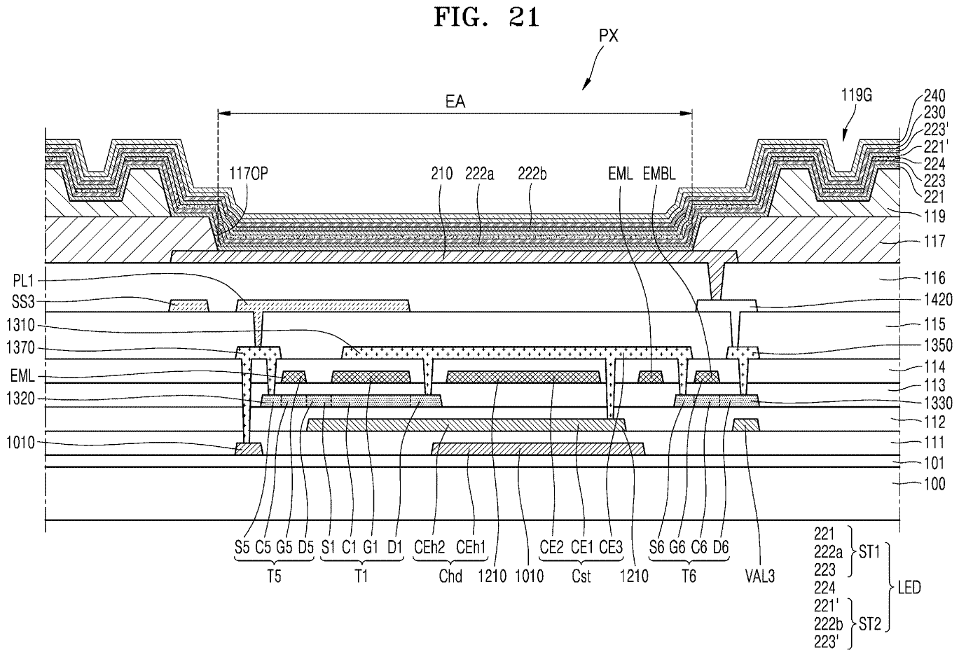

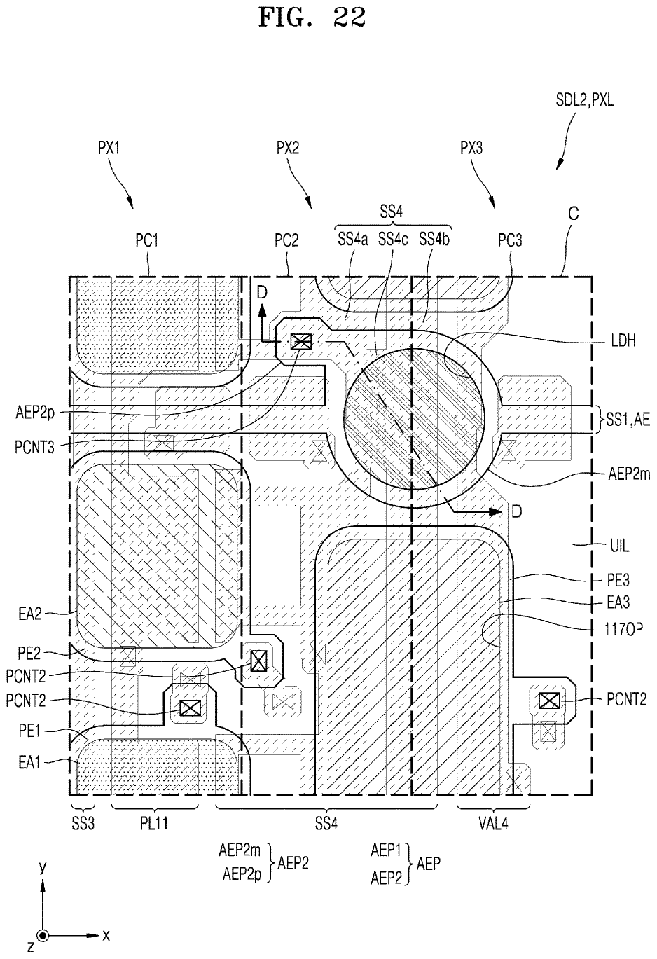

Accordingly, in the second pad portion AEP2 used for the laser drilling process, the third contact hole PCNT3 may be disposed at a side rather than at the center of the second pad portion AEP2 so as to avoid overlapping with a laser drilling opening LDH formed in the second pad portion AEP2. Details of the laser drilling opening LDH and the arrangement of the third contact hole PCNT3 are described with reference to FIGS. 21 and 22.

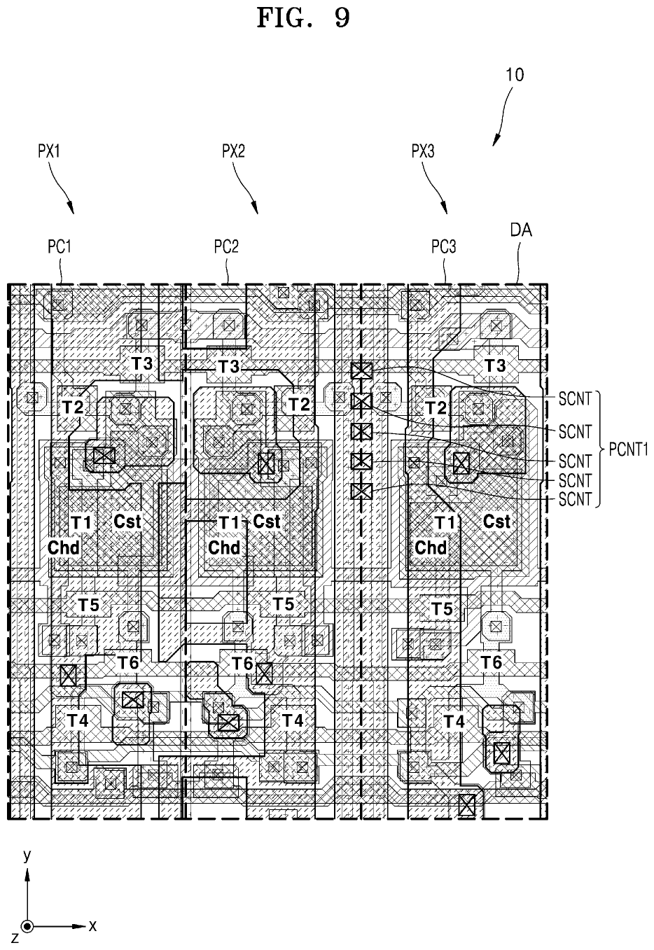

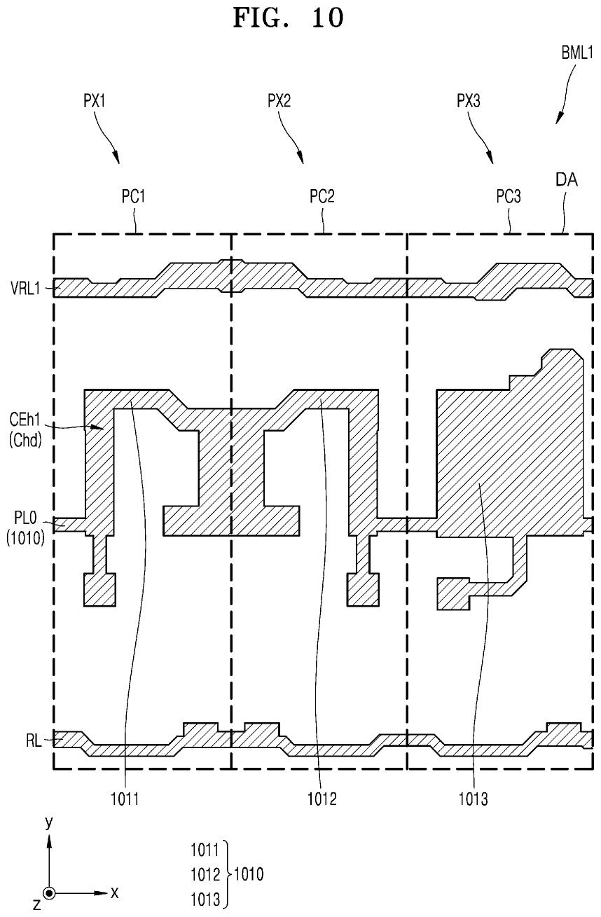

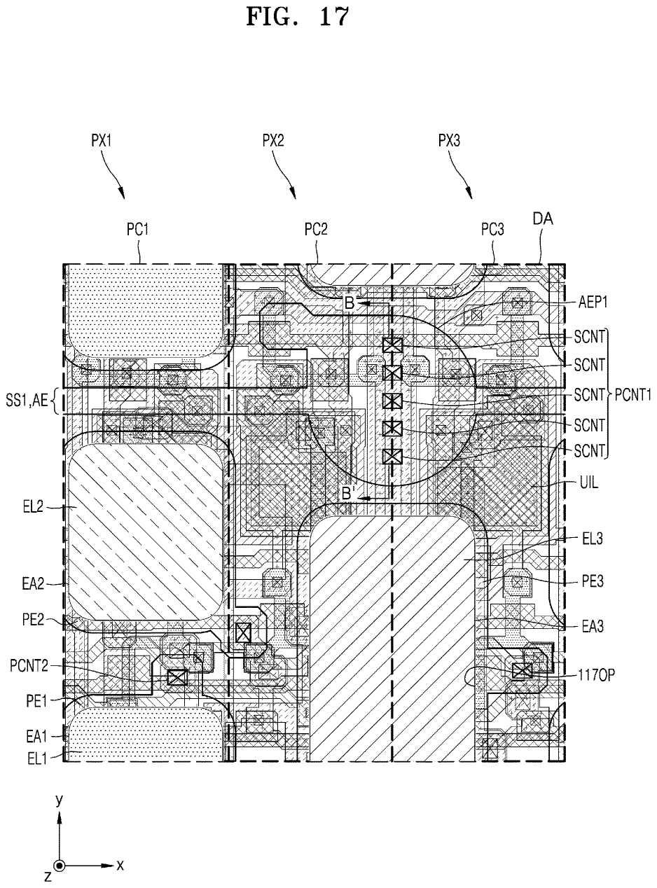

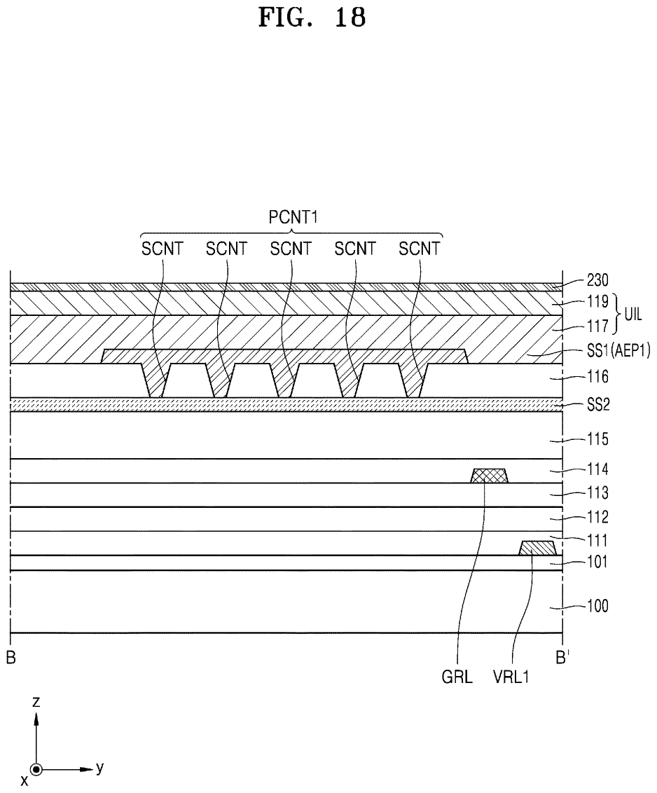

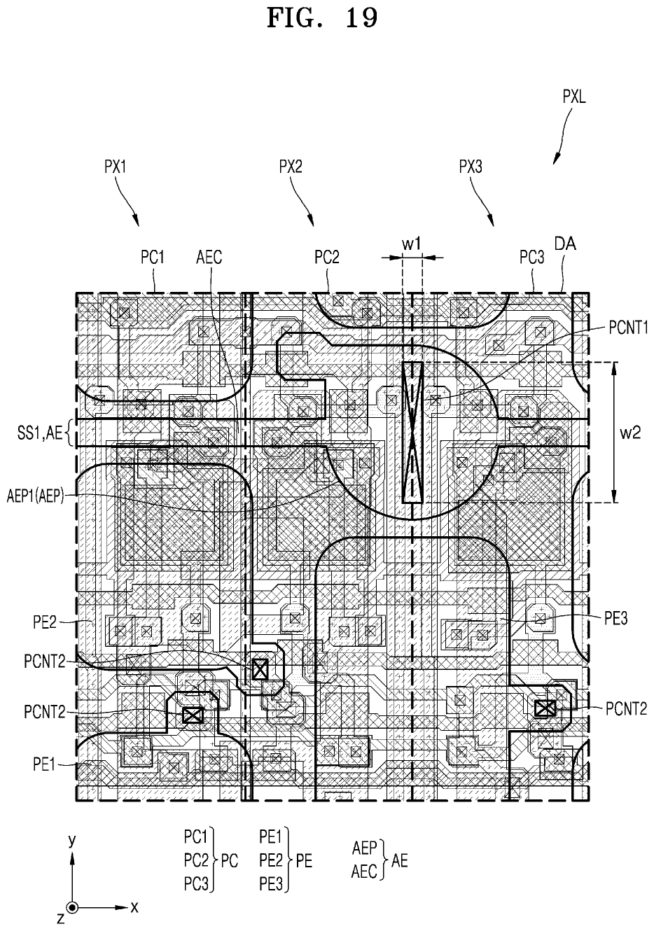

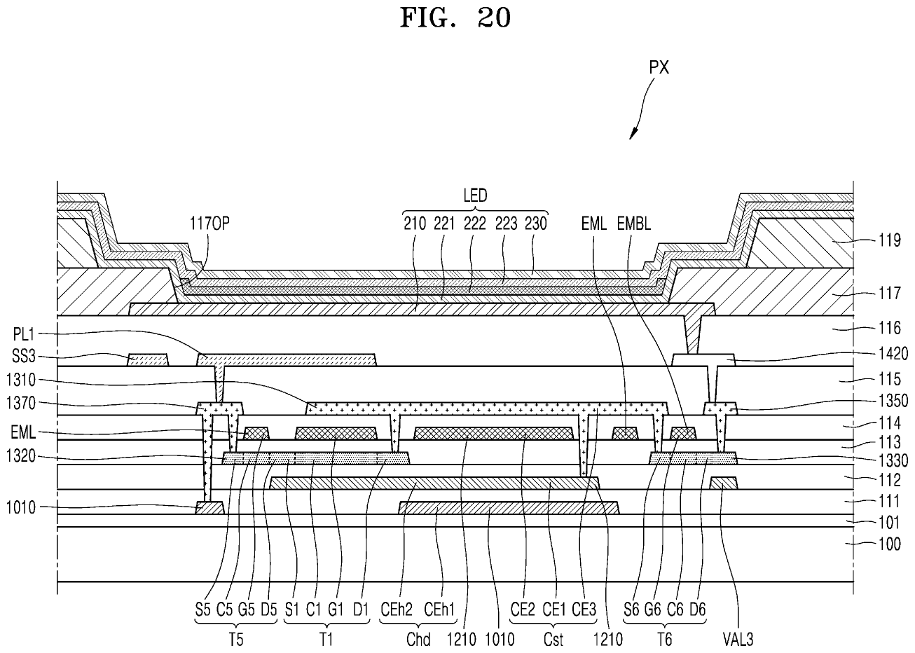

FIG. 9 is a layout diagram schematically illustrating the structure of pixel circuits in pixels, according to an embodiment. FIG. 9 may correspond to the enlarged structure of region A of FIG. 8. FIGS. 10 to 17 are layer-by-layer layout diagrams illustrating conductive patterns constituting the pixel circuit of FIG. 9. FIG. 18 is a cross-sectional view schematically illustrating a cross-section including a pad portion according to an embodiment. FIG. 18 may correspond to the cross-section taken along line B-B′ of FIG. 17. FIG. 19 is a schematic plan view of a pad portion according to an embodiment. FIG. 19 corresponds to a modification of FIG. 16. FIG. 20 is a cross-sectional view schematically illustrating a portion of a structure of a pixel circuit according to an embodiment.

FIG. 9 is a layout diagram schematically illustrating the positions of a plurality of transistors T1, T2, T3, T4, T5, and T6 and a plurality of capacitors Cst and Chd in pixels PX included in a display device 10 according to an embodiment, FIGS. 10 to 15 are layer-by-layer layout diagrams schematically illustrating elements such as the plurality of transistors T1, T2, T3, T4, T5, and T6 and the plurality of capacitors Cst and Chd illustrated in FIG. 9, FIG. 16 is a layout diagram schematically illustrating first to third pixel electrodes PE1, PE2, and PE3 that may be electrically connected to pixel circuits of FIG. 15, and FIG. 17 is a layout diagram in which first to third emission layers EL1, EL2, and EL3 are respectively disposed on the first to third pixel electrodes PE1, PE2, and PE3 of FIG. 16.

Referring to FIGS. 9 to 17, the display device 10 may have a structure in which sets of first to third pixels PX1, PX2, and PX3 are repeatedly disposed in the first direction (e.g., the x-axis direction). In some embodiments, the sets of the first to third pixels PX1, PX2, and PX3 may also be repeatedly disposed in the second direction (e.g., in the y-axis direction). Sets of the first to third pixels PX1, PX2, and PX3 may be arranged such that the structure illustrated in FIG. 9 is repeatedly disposed in the first direction (e.g., the x-axis direction) and/or the second direction (e.g., the y-axis direction). In some embodiments, an extended set including the first to third pixels PX1, PX2, and PX3 may be repeatedly disposed in the first direction and/or the second direction.

For reference, the areas where the first to third pixels PX1, PX2, and PX3 illustrated in FIGS. 9 to 17 are disposed may be areas where the first pixel circuit PC1 included in the first pixel PX1, the second pixel circuit PC2 included in the second pixel PX2, and the third pixel circuit PC3 included in the third pixel PX3 are disposed. The first pixel circuit PC1 of the first pixel PX1 may be referred to as a first color pixel circuit, the second pixel circuit PC2 of the second pixel PX2 may be referred to as a second color pixel circuit, and the third pixel circuit PC3 of the third pixel PX3 may be referred to as a third color pixel circuit. For example, the first color may be red, the second color may be green, and the third color may be blue.

The first pixel circuit PC1 and the second pixel circuit PC2 to be described below with reference to FIGS. 9 to 20 may be arranged to be approximately symmetrical with respect to a boundary between the first pixel circuit PC1 and the second pixel circuit PC2. The third pixel PX3 may have a shape different from that of the second pixel PX2. In another embodiment, the second pixel PX2 and the third pixel PX3 may also be arranged to be approximately symmetrical with respect to a boundary between the second pixel PX2 and the third pixel PX3.

Respective elements to be described with reference to FIGS. 9 to 20 may be disposed on a substrate (100, FIG. 18). The substrate 100 may include a glass material, a ceramic material, a metal material, a plastic material, or a flexible or bendable material. When the substrate 100 is flexible or bendable, the substrate 100 may include polymer resin, such as polyethersulfone (PES), polyacrylate, polyether imide (PEI), polyethylene naphthalate (PEN), polyethylene terephthalate (PET), polyphenylene sulfide (PPS), polyarylate, polyimide (PI), polycarbonate, or cellulose acetate propionate (CAP). The substrate 100 may have a single-layer or multilayer structure including the material described above. In the case of the multilayer structure, the substrate 100 may further include an inorganic layer. For example, the substrate 100 may have a structure in which a layer including the aforementioned polymer resin and a barrier layer including an inorganic insulating material are alternately stacked.

Referring to FIGS. 10 and 20 together, a buffer layer 101 may be disposed on the substrate 100. The buffer layer 101 may include silicon oxide, silicon nitride, or silicon oxynitride. The buffer layer 101 may prevent metal atoms or impurities from diffusing from the substrate 100 into a semiconductor layer ACT disposed thereon. In addition, the buffer layer 101 may control a rate of heat supply during a crystallization process for forming the semiconductor layer ACT so that the semiconductor layer ACT is uniformly crystallized.

A first bottom metal layer BML1 may be disposed on the buffer layer 101. The first bottom metal layer BML1 may include a lower conductive pattern 1010, a first reference voltage line VRL1, and a repair line RL. Each of the lower conductive pattern 1010, the first reference voltage line VRL1, and the repair line RL may extend in the first direction (e.g., the x-axis direction).

The first bottom metal layer BML1 may include a metal material. For example, the first bottom metal layer BML1 may include at least one material such as aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the first bottom metal layer BML1 may have a single-layer structure including molybdenum, a double-layer structure in which a molybdenum layer and a titanium layer are stacked, or a triple-layer structure in which a titanium layer, an aluminum layer, and a titanium layer are stacked.

The lower conductive pattern 1010 may be set to a constant voltage. The lower conductive pattern 1010 may be referred to as a lower driving voltage line PL0. For example, the lower driving voltage line PL0 may have the same voltage level as the driving voltage line (see PL of FIG. 7). The lower driving voltage line PL0 may be provided as the driving voltage line (see PL of FIG. 7) by being electrically connected to a first upper driving voltage line PL11 and a second upper driving voltage line PL12 to be described below with reference to FIG. 15, thereby allowing a driving voltage ELVDD to be applied. The driving voltage line (see PL of FIG. 7), which includes the lower driving voltage line PL0, may be electrically connected to the driving voltage supply line 20 in the peripheral area PA, as illustrated in FIG. 6.

The lower conductive pattern 1010 may have a symmetrical shape along an imaginary line extending in the second direction (e.g., the y-axis direction) and disposed at the boundary between the first pixel circuit PC1 and the second pixel circuit PC2. For example, the lower conductive pattern 1010 may be arranged to be symmetrical about a boundary extending in the second direction (e.g., the y-axis direction) between the first pixel circuit PC1 and the second pixel circuit PC2. The lower conductive pattern 1010 may include a first hold electrode CEh1 of a hold capacitor Chd. For example, the lower conductive pattern 1010 may include the first hold electrodes CEh1 of the hold capacitors Chd of the first to third pixels PX1, PX2, and PX3, and the first hold electrodes CEh1 of the hold capacitors Chd of the first to third pixels PX1, PX2, and PX3 may be connected to each other to form a single body.

The lower conductive pattern 1010 may include a first portion 1011 disposed to correspond to the first pixel circuit PC1, a second portion 1012 disposed to correspond to the second pixel circuit PC2, and a third portion 1013 disposed to correspond to the third pixel circuit PC3. The first portion 1011, the second portion 1012, and the third portion 1013 may each partially overlap a first conductive pattern (see 1020 of FIG. 11) to be described below. A partial region of each of the first portion 1011, the second portion 1012, and the third portion 1013, which overlaps the first conductive pattern (see 1020 of FIG. 11) in a plan view, may be the first hold electrode CEh1 of the hold capacitor (see Chd of FIG. 11).

The first portion 1011 and the second portion 1012 of the lower conductive pattern 1010 may have a loop shape with a lower side open or a rectangular frame shape with a lower side open. The first portion 1011 and the second portion 1012 may be symmetrical with respect to an imaginary line forming the boundary between the first pixel circuit PC1 and the second pixel circuit PC2, and the first portion 1011 and the second portion 1012 may be integrally formed as a single body. For example, the first portion 1011 and the second portion 1012 may be symmetrical with respect to a boundary between the first pixel circuit PC1 and the second pixel circuit PC2. The third portion 1013 may have a rectangular shape with a protruding portion at an upper right side.

Because the first portion 1011 and the second portion 1012 of the lower conductive pattern 1010 have a shape with a lower side open, a portion overlapping the data line DL may be reduced. A separate structure for shielding the data line DL may not be required due to the structure of the first portion 1011 and the second portion 1012 of the lower conductive pattern 1010. Accordingly, the occurrence of capacitance between the data line DL and the lower conductive pattern 1010 may be reduced, and crosstalk may be prevented from occurring in adjacent pixels through coupling between the data line DL and the lower conductive pattern 1010.

The repair line RL may be disposed on one side of the lower conductive pattern 1010. The repair line RL may be a spare line configured to be used when a defect occurs in a signal line or a voltage line included in the first to third pixel circuits PC1, PC2, and PC3 of the first to third pixels PX1, PX2, and PX3. The repair line RL may extend along the first direction (e.g., the x-axis direction) to pass through the first to third pixel circuits PC1, PC2, and PC3. For example, the repair line RL may pass through pixel circuits disposed in the same row as the first to third pixel circuits PC1, PC2, and PC3. When the pixel circuit is defective, the repair line RL may isolate the light-emitting diode LED from the defective pixel circuit and connect the light-emitting diode LED to a dummy circuit through the repair line RL. The dummy circuit may generate a driving current corresponding to the data signal and supply the driving current to the light-emitting diode LED through the repair line RL so that the light-emitting diode LED may operate normally.

The first reference voltage line VRL1 may be disposed on the other side of the lower conductive pattern 1010. The first reference voltage line VRL1 may be a horizontal reference voltage line extending approximately in the first direction (e.g., the x-axis direction). The first reference voltage line VRL1 may be electrically connected to a second reference voltage line VRL2, which is a vertical reference voltage line to be described below with reference to FIG. 14, and a fourth connection pattern 1340 to transmit the reference voltage to each pixel circuit.

Referring to FIGS. 11 and 20 together, a first insulating layer 111 may be disposed on the first bottom metal layer BML1, and the second bottom metal layer BML2 may be disposed on the first insulating layer 111. The second bottom metal layer BML2 may include a first conductive pattern 1020, a second conductive pattern 1030, a first write gate line GWLa, a second initialization voltage line VAL2, and a third initialization voltage line VAL3.

The first insulating layer 111 may include an inorganic insulating material. The first insulating layer 111 may include, for example, silicon oxide, silicon nitride, silicon oxynitride, or aluminum oxide.

The second bottom metal layer BML2 may include a metal material. Specifically, the second bottom metal layer BML2 may include at least one material such as aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the second bottom metal layer BML2 may have a single-layer structure including molybdenum, a double-layer structure in which a molybdenum layer and a titanium layer are stacked, or a triple-layer structure in which a titanium layer, an aluminum layer, and a titanium layer are stacked.

The first conductive pattern 1020 may have an isolated shape, for example, an island-shaped conductive pattern that is electrically isolated from other conductive patterns. The first conductive pattern 1020 may be disposed to correspond to each of the first pixel circuit PC1, the second pixel circuit PC2, and the third pixel circuit PC3. The first conductive pattern 1020 may have a symmetrical shape along an imaginary line extending in the second direction (e.g., the y-axis direction) at the boundary between the first pixel circuit PC1 and the second pixel circuit PC2. For example, the first conductive pattern 1020 may include first and second portions disposed on opposite sides of the boundary between the first pixel circuit PC1 and the second pixel circuit PC2, the first and second portions having substantially corresponding shape. The first conductive pattern 1020 may be disposed to overlap at least a portion of the first bottom metal layer BML1 described above with reference to FIG. 10. For example, the first conductive pattern 1020 may at least partially overlap the lower conductive pattern 1010 described above with reference to FIG. 10.

The first conductive pattern 1020 may include a second hold electrode CEh2 of the hold capacitor Chd. The first hold electrode CEh1 of the hold capacitor Chd described above with reference to FIG. 10 may overlap the second hold electrode CEh2 of the hold capacitor Chd to form the hold capacitor Chd.

The first conductive pattern 1020 may include a lower electrode CE1 of a storage capacitor Cst. In an embodiment, the first conductive pattern 1020 may include a lower gate electrode (e.g., a first-2 gate electrode) of a first transistor (see T1 of FIG. 13) overlapping a first semiconductor layer (see A1 of FIG. 13) of the first transistor (see T1 of FIG. 13). The second hold electrode CEh2 of the hold capacitor Chd and the lower electrode CE1 of the storage capacitor Cst may be integrally provided to form a single body and may be connected to the second node N2 described above with reference to FIG. 7.

Each of the first write gate line GWLa, the second initialization voltage line VAL2, and the third initialization voltage line VAL3 may extend in the first direction (e.g., the x-axis direction) to pass through areas corresponding to the first pixel circuit PC1, the second pixel circuit PC2, and the third pixel circuit PC3.

The first write gate line GWLa may be disposed on one side of the first conductive pattern 1020, and the second initialization voltage line VAL2 and the third initialization voltage line VAL3 may be disposed on the other side of the first conductive pattern 1020. For example, in a plan view based on FIG. 11, the first write gate line GWLa may be disposed above the first conductive pattern 1020, and the second initialization voltage line VAL2 and the third initialization voltage line VAL3 may be disposed below the first conductive pattern 1020. For example, the first conductive pattern 1020 may be disposed between the first write gate line GWLa and the third initialization voltage line VAL3.

The second conductive pattern 1030 may be disposed on the opposite side of the third initialization voltage line VAL3 with respect to the second initialization voltage line VAL2. The second conductive pattern 1030 may have an isolated shape, for example, an island-shaped conductive pattern that is electrically isolated from other conductive patterns. The second conductive pattern 1030 may be a repair pattern that is disposed to overlap the repair line RL described above with reference to FIG. 10 and is bonded to and electrically connected to the repair line RL in response to detection of a defect in a signal line or a voltage line.

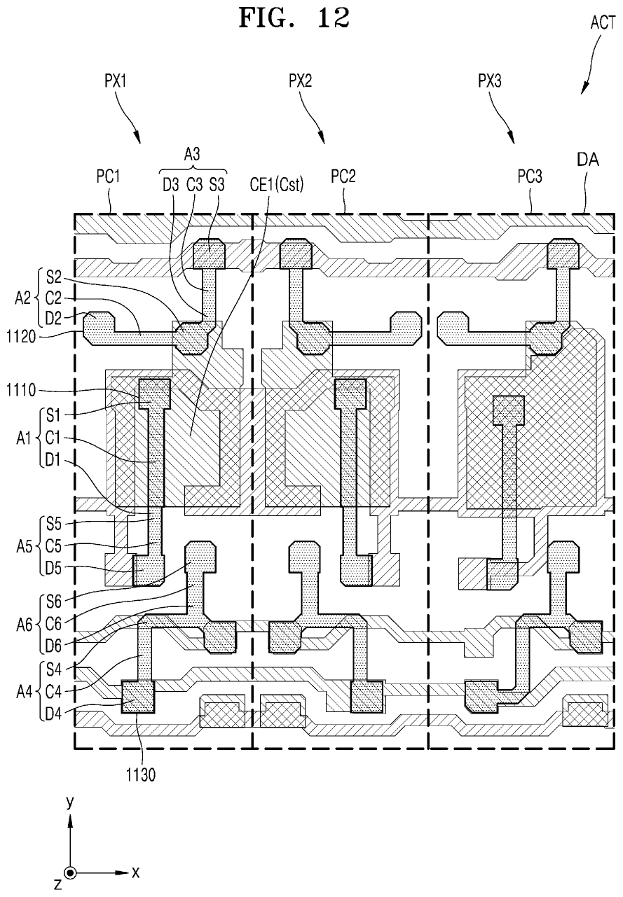

Referring to FIGS. 12 and 20 together, a second insulating layer 112 may be disposed on the second bottom metal layer BML2, and a semiconductor layer ACT may be disposed on the second insulating layer 112. The semiconductor layer ACT may include a first semiconductor pattern 1110, a second semiconductor pattern 1120, and a third semiconductor pattern 1130.

The second insulating layer 112 may include an inorganic insulating material. The second insulating layer 112 may include, for example, silicon oxide, silicon nitride, silicon oxynitride, or aluminum oxide.

The semiconductor layer ACT may include an oxide semiconductor material. For example, the first to third semiconductor patterns 1110, 1120, and 1130 may include the same material. In an embodiment, the first to third semiconductor patterns 1110, 1120, and 1130 may each include an oxide semiconductor material of at least one of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In another embodiment, the first to third semiconductor patterns 1110, 1120, and 1130 may each include polysilicon or amorphous silicon.

Each of the first semiconductor pattern 1110, the second semiconductor pattern 1120, and the third semiconductor pattern 1130 may have an isolated shape, for example, an island-shaped semiconductor pattern that is electrically isolated from other semiconductor patterns. For example, the first semiconductor pattern 1110, the second semiconductor pattern 1120, and the third semiconductor pattern 1130 may be spaced apart from each other. Each of the first semiconductor pattern 1110, the second semiconductor pattern 1120, and the third semiconductor pattern 1130 may be disposed to correspond to each of the first pixel circuit PC1, the second pixel circuit PC2, and the third pixel circuit PC3.

The first semiconductor pattern 1110 may include a first semiconductor layer A1 and a fifth semiconductor layer A5. For example, the first semiconductor layer A1 and the fifth semiconductor layer A5 may be integrally connected to each other to form a single body. The second semiconductor pattern 1120 may include a second semiconductor layer A2 and a third semiconductor layer A3. For example, the second semiconductor layer A2 and the third semiconductor layer A3 may be integrally connected to each other to form a single body. The third semiconductor pattern 1130 may include a fourth semiconductor layer A4 and a sixth semiconductor layer A6. For example, the fourth semiconductor layer A4 and the sixth semiconductor layer A6 may be integrally connected to each other to form a single body.

The first semiconductor pattern 1110 may be disposed in each of the first pixel circuit PC1, the second pixel circuit PC2, and the third pixel circuit PC3. The first semiconductor pattern 1110 may have a shape extending in the second direction (e.g., the y-axis direction). For example, the first semiconductor pattern 1110 may have an “I” shape. The first semiconductor pattern 1110 may include a first semiconductor layer A1 of a first transistor (see T1 of FIG. 13) and a fifth semiconductor layer A5 of a fifth transistor (see T5 of FIG. 13). The first semiconductor layer A1 and the fifth semiconductor layer A5 may be integrally connected to each other to form a single body.

The first semiconductor layer A1 may include a first channel region C1 overlapping a first gate electrode G1 of a first transistor T1 to be described below with reference to FIG. 13, a first source region S1 disposed on one side of the first channel region C1, and a first drain region D1 disposed on the other side of the first channel region C1.

The second semiconductor layer A2 may include a second channel region C2 overlapping a second gate electrode G2 of a second transistor T2 to be described below with reference to FIG. 13, a second source region S2 disposed on one side of the second channel region C2, and a second drain region D2 disposed on the other side of the second channel region C2.

The second semiconductor pattern 1120 may be disposed in each of the first pixel circuit PC1, the second pixel circuit PC2, and the third pixel circuit PC3. The second semiconductor pattern 1120 may have a bent shape. For example, the second semiconductor pattern 1120 may have an “L” shape or an inverted “L” shape. The second semiconductor pattern 1120 may include a second semiconductor layer A2 of a second transistor (see T2 of FIG. 13) and a third semiconductor layer A3 of a third transistor (see T3 of FIG. 13). The second semiconductor layer A2 and the third semiconductor layer A3 may be integrally connected to each other to form a single body.

The third semiconductor layer A3 may include a third channel region C3 overlapping a third gate electrode G3 of a third transistor T3 to be described below with reference to FIG. 13, a third source region S3 disposed on one side of the third channel region C3, and a third drain region D3 disposed on the other side of the third channel region C3.

The fourth semiconductor layer A4 may include a fourth channel region C4 overlapping a fourth gate electrode G4 of a fourth transistor T4 to be described below with reference to FIG. 13, a fourth source region S4 disposed on one side of the fourth channel region C4, and a fourth drain region D4 disposed on the other side of the fourth channel region C4.

The third semiconductor pattern 1130 may be disposed in each of the first pixel circuit PC1, the second pixel circuit PC2, and the third pixel circuit PC3. The third semiconductor pattern 1130 may have a shape that is bent multiple times. The third semiconductor pattern 1130 may include a fourth semiconductor layer A4 of a fourth transistor (see T4 of FIG. 13) and a sixth semiconductor layer A6 of a sixth transistor (see T6 of FIG. 13). The fourth semiconductor layer A4 and the sixth semiconductor layer A6 may be integrally connected to each other to form a single body.

The fifth semiconductor layer A5 may include a fifth channel region C5 overlapping a fifth gate electrode G5 of a fifth transistor T5 to be described below with reference to FIG. 13, a fifth source region S5 disposed on one side of the fifth channel region C5, and a fifth drain region D5 disposed on the other side of the fifth channel region C5.

The sixth semiconductor layer A6 may include a sixth channel region C6 overlapping a sixth gate electrode G6 of a sixth transistor T6 to be described below with reference to FIG. 13, a sixth source region S6 disposed on one side of the sixth channel region C6, and a sixth drain region D6 disposed on the other side of the sixth channel region C6.

Referring to FIGS. 13 and 20, a third insulating layer 113 may be disposed on the semiconductor layer ACT, and a gate layer GAT may be disposed on the third insulating layer 113. The gate layer GAT may include a third conductive pattern 1210, a fourth conductive pattern 1220, a second write gate line GWLb, a reference gate line GRL, a first emission control line EML, a second emission control line EMBL, an initialization gate line GIL, and a first initialization voltage line VAL1.

The third insulating layer 113 may include an inorganic insulating material. The third insulating layer 113 may include, for example, silicon oxide, silicon nitride, silicon oxynitride, or aluminum oxide.

The gate layer GAT may include a metal, an alloy, a conductive metal oxide, or a transparent conductive material. For example, the gate layer GAT may include silver (Ag), an Ag-containing alloy, molybdenum (Mo), a Mo-containing alloy, aluminum (Al), an Al-containing alloy, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The gate layer GAT may have a multilayer structure. For example, the gate layer GAT may have a two-layer structure of Mo/Al or a three-layer structure of Mo/Al/Mo.

Each of the third conductive pattern 1210 and the fourth conductive pattern 1220 may have an isolated shape, for example, an island-shaped conductive pattern that is electrically isolated from other conductive patterns. For example, the third conductive pattern 1210 and the fourth conductive pattern 1220 may be spaced apart from each other. Each of the third conductive pattern 1210 and the fourth conductive pattern 1220 may be disposed to correspond to each of the first pixel circuit PC1, the second pixel circuit PC2, and the third pixel circuit PC3.

The third conductive pattern 1210 may overlap at least a portion of the first semiconductor pattern 1110. The third conductive pattern 1210 may include the first gate electrode G1 of the first transistor T1 overlapping the first semiconductor layer A1 of the first transistor T1. The first gate electrode G1 may be an upper gate electrode (e.g., a first-1 gate electrode).

The third conductive pattern 1210 may include an intermediate electrode CE2 of a storage capacitor Cst connected to the first node N1 described above with reference to FIG. 7. The third conductive pattern 1210 may partially overlap the first conductive pattern (see 1020 of FIG. 11), with the first conductive pattern 1020 being disposed in a layer below the third conductive pattern 1210. A portion of the third conductive pattern 1210 that overlaps the first conductive pattern (see 1020 of FIG. 11) in a plan view may be the intermediate electrode CE2 of the storage capacitor Cst. The intermediate electrode CE2 of the storage capacitor Cst may overlap the lower electrode (see CE1 of FIG. 12) and the upper electrode (see CE3 of FIG. 14) of the storage capacitor Cst to form the storage capacitor Cst. The first gate electrode G1 of the first transistor T1 and the intermediate electrode CE2 of the storage capacitor Cst may be integrally provided to form a single body.

The fourth conductive pattern 1220 may overlap at least a portion of the second semiconductor pattern 1120. The fourth conductive pattern 1220 may include the second gate electrode G2 of the second transistor T2 overlapping the second semiconductor layer A2 of the second transistor T2.

Each of the second write gate line GWLb, the reference gate line GRL, the first emission control line EML, the initialization gate line GIL, the second emission control line EMBL, and the first initialization voltage line VAL1 may extend approximately in the first direction (e.g., the x-axis direction) so as to pass through the first pixel circuit PC1, the second pixel circuit PC2, and the third pixel circuit PC3.

In a plan view, the second write gate line GWLb and the reference gate line GRL may each be disposed on one side of the third conductive pattern 1210, and the first emission control line EML, the initialization gate line GIL, the second emission control line EMBL, and the first initialization voltage line VAL1 may each be disposed on the other side of the third conductive pattern 1210. For example, in a plan view based on FIG. 13, each of the second write gate line GWLb and the reference gate line GRL may be disposed above the third conductive pattern 1210, and each of the first emission control line EML, the initialization gate line GIL, the second emission control line EMBL, and the first initialization voltage line VAL1 may be disposed below the third conductive pattern 1210.

The second write gate line GWLb may be disposed on the first write gate line GWLa and at least partially overlap the first write gate line GWLa. For example, a write gate line GWL may include the first write gate line GWLa and the second write gate line GWLb disposed in different layers.

The reference gate line GRL may overlap at least a portion of the second semiconductor pattern 1120. The reference gate line GRL may include the third gate electrode G3 of the third transistor T3 overlapping the third semiconductor layer A3 of the third transistor T3.

The first emission control line EML may overlap at least a portion of the first semiconductor pattern 1110. The first emission control line EML may include the fifth gate electrode G5 of the fifth transistor T5 overlapping the fifth semiconductor layer A5 of the fifth transistor T5.

The initialization gate line GIL may overlap at least a portion of the third semiconductor pattern 1130. The initialization gate line GIL may include the fourth gate electrode G4 of the fourth transistor T4 overlapping the fourth semiconductor layer A4 of the fourth transistor T4.

The second emission control line EMBL may overlap at least a portion of the third semiconductor pattern 1130. The second emission control line EMBL may include the sixth gate electrode G6 of the sixth transistor T6 overlapping the sixth semiconductor layer A6 of the sixth transistor T6.

Referring to FIGS. 14 and 20, a fourth insulating layer 114 may be disposed on the gate layer GAT, and a first source/drain layer SDL1 may be disposed on the fourth insulating layer 114. The first source/drain layer SDL1 may include a data line DL, a second reference voltage line VRL2, a first connection pattern 1310, a second connection pattern 1320, a third connection pattern 1330, a fourth connection pattern 1340, a fifth connection pattern 1350, a sixth connection pattern 1360, and a seventh connection pattern 1370.

The fourth insulating layer 114 may include an inorganic insulating material. The fourth insulating layer 114 may include, for example, silicon oxide, silicon nitride, silicon oxynitride, or aluminum oxide.

The first source/drain layer SDL1 may include a metal, an alloy, a conductive metal oxide, or a transparent conductive material. For example, the first source/drain layer SDL1 may include silver (Ag), an Ag-containing alloy, molybdenum (Mo), a Mo-containing alloy, aluminum (Al), an Al-containing alloy, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), ITO, or IZO. The first source/drain layer SDL1 may have a multilayer structure. For example, the first source/drain layer SDL1 may have a two-layer structure of Ti/Al or a three-layer structure of Ti/Al/Ti.

The data line DL, the first connection pattern 1310, the second connection pattern 1320, the third connection pattern 1330, the fourth connection pattern 1340, the fifth connection pattern 1350, the sixth connection pattern 1360, and the seventh connection pattern 1370 may be disposed to correspond to the first pixel circuit PC1, the second pixel circuit PC2, and the third pixel circuit PC3.

The data line DL may extend along the second direction (e.g., the y-axis direction) crossing the first direction (e.g., the x-axis direction). The data line DL may be electrically connected to the second drain region (see D2 of FIG. 12) of the second semiconductor layer A2 of the second transistor T2 through a first contact hole CNT1 passing through at least one insulating layer disposed between the second semiconductor layer A2 and the data line DL. The data lines DL may be respectively disposed to correspond to the first pixel circuit PC1, the second pixel circuit PC2, and the third pixel circuit PC3. For example, the data line DL disposed in the first pixel circuit PC1 may be configured to transmit a data signal to a red pixel, the data line DL disposed in the second pixel circuit PC2 may be configured to transmit a data signal to a green pixel, and the data line DL disposed in the third pixel circuit PC3 may be configured to transmit a data signal to a blue pixel. For example, the data lines DL respectively disposed in the first pixel circuit PC1, the second pixel circuit PC2, and the third pixel circuit PC3 may be electrically connected to the second transistor T2 of the first pixel PX1, the second transistor T2 of the second pixel PX2, and the second transistor T2 of the third pixel PX3, respectively.

The first connection pattern 1310 may be electrically connected to the first semiconductor pattern (see 1110 of FIG. 12) through a second contact hole CNT2 passing through at least one insulating layer disposed between the first connection pattern 1310 and the first semiconductor pattern (see 1110 of FIG. 12). For example, the first connection pattern 1310 may be connected to the first source region (see S1 of FIG. 12) of the first semiconductor layer A1 of the first transistor T1 through the second contact hole CNT2.

The first connection pattern 1310 may be electrically connected to the third semiconductor pattern (see 1130 of FIG. 12) through a third contact hole CNT3 passing through at least one insulating layer disposed between the first connection pattern 1310 and the first semiconductor pattern (see 1130 of FIG. 12). For example, the first connection pattern 1310 may be connected to the sixth drain region (see D6 of FIG. 12) of the sixth semiconductor layer A6 of the sixth transistor T6 through the third contact hole CNT3.

The first connection pattern 1310 may include an upper electrode CE3 of the storage capacitor Cst. The first connection pattern 1310 may partially overlap the third conductive pattern (see 1210 of FIG. 13) and the first conductive pattern (see 1020 of FIG. 11). A portion of the first connection pattern 1310 that overlap the third conductive pattern (see 1210 of FIG. 13) and the first conductive pattern (see 1020 of FIG. 11) in a plan view may be the upper electrode CE3 of the storage capacitor Cst. The upper electrode CE3 of the storage capacitor Cst may be electrically connected to the lower electrode (see CE1 of FIG. 12) of the storage capacitor Cst through a fourth contact hole CNT4 passing through at least one insulating layer disposed between the upper electrode CE3 of the storage capacitor Cst and the lower electrode CE1 of the storage capacitor Cst. The upper electrode CE3 of the storage capacitor Cst may overlap the lower electrode (see CE1 of FIG. 12) and the intermediate electrode (see CE2 of FIG. 13) of the storage capacitor Cst to form the storage capacitor Cst.

The second connection pattern 1320 may connect the second gate electrode G2 of the second transistor T2 to the second write gate line GWLb. The second connection pattern 1320 may be electrically connected to the second write gate line GWLb through a fifth contact hole CNT5 passing through at least one insulating layer disposed between the second connection pattern 1320 and the second write gate line GWLb. For example, the second connection pattern 1320 may be directly connected to the second write gate line GWLb through the fifth contact hole CNT5, without passing through a separate contact metal.

The third connection pattern 1330 may connect the second semiconductor pattern 1120 to the third conductive pattern 1210. The third connection pattern 1330 may be electrically connected to the second semiconductor pattern 1120 and the third conductive pattern 1210 through a sixth contact hole CNT6 and a seventh contact hole CNT7 passing through at least one insulating layer disposed between the third connection pattern 1330 and the second semiconductor pattern 1120 and between the third connection pattern 1330 and the third conductive pattern 1210. For example, one side of the third connection pattern 1330 may be connected to the second semiconductor pattern 1120 through the sixth contact hole CNT6, and the other side of the third connection pattern 1330 may be connected to the third conductive pattern 1210 through the seventh contact hole CNT7. The third connection pattern 1330 may connect the second drain region (see D2 of FIG. 11) of the second semiconductor layer A2 of the second transistor T2, the third drain region (see D3 of FIG. 12) of the third semiconductor layer A3 of the third transistor T3, and the first gate electrode G1 of the first transistor T1 to each other. The third connection pattern 1330 may connect the second drain region (see D2 of FIG. 12) of the second semiconductor layer A2 of the second transistor T2, the third drain region (see D3 of FIG. 12) of the third semiconductor layer A3 of the third transistor T3, and the lower electrode CE1 of the storage capacitor Cst to each other.

The second reference voltage line VRL2 may extend in the second direction (e.g., the y-axis direction). The second reference voltage line VRL2 may be disposed symmetrically between the first pixel circuit PC1 and the second pixel circuit PC2 so that the second reference voltage line VRL2 may be shared by the first pixel PX1 and the second pixel PX2. For example, the second reference voltage line VRL2 may be disposed at a boundary between the first pixel circuit PC1 and the second pixel circuit PC2, such that portions of the second reference voltage line VRL2 extend into both the first pixel PX1 and the second pixel PX2 to supply the reference voltage thereto. The second reference voltage line VRL2 may be electrically connected to the second semiconductor pattern (see 1120 of FIG. 12) through an eighth contact hole CNT8. In some embodiments, the second reference voltage line VRL2 may be electrically connected to the first reference voltage line (see VRL1 of FIG. 10) through the eighth contact hole CNT8. Accordingly, a reference voltage Vref may be applied to the third source region S3 of the third semiconductor layer A3 of the third transistor T3 through the second reference voltage line VRL2.

The fourth connection pattern 1340 may be disposed in the third pixel circuit PC3 and may perform the same role as the second reference voltage line VRL2 described above. In other words, the fourth connection pattern 1340 may electrically connect the first reference voltage line VRL1 to the second semiconductor pattern 1120 through a contact hole passing through at least one insulating layer. Accordingly, the reference voltage Vref may be applied to the third source region (see S3 of FIG. 12) of the third semiconductor layer A3 of the third transistor T3 of the third pixel circuit PC3 through the fourth connection pattern 1340.

The fifth connection pattern 1350 may be disposed so that the repair line (see RL of FIG. 10) and the pixel circuit are connectable to each other when a defect occurs in a signal line or a voltage line included in the pixel circuit. When such a defect occurs, the second conductive pattern 1030 may be bonded to and electrically connected to the repair line (see RL of FIG. 10). For example, the fifth connection pattern 1350 may be electrically connected to the second conductive pattern (see 1030 of FIG. 11) and the third semiconductor pattern (see 1130 of FIG. 12), which function as repair patterns, through a ninth contact hole CNT9 and a tenth contact hole CNT10.

The sixth connection pattern 1360 may be electrically connected to the third semiconductor pattern 1130 and the first initialization voltage line VAL1 through an eleventh contact hole CNT11 and a twelfth contact hole CNT12 passing through at least one insulating layer. For example, one side of the sixth connection pattern 1360 may be connected to the third semiconductor pattern 1130 through the eleventh contact hole CNT11, and the other side of the sixth connection pattern 1360 may be connected to the first initialization voltage line VAL1 through the twelfth contact hole CNT12. The sixth connection pattern 1360 disposed in the first pixel circuit PC1 may connect the first initialization voltage line VAL1 to the fourth source region S4 of the fourth semiconductor layer A4 of the fourth transistor T4 of the first pixel circuit PC1. The sixth connection pattern 1360 disposed in the second pixel circuit PC2 may connect the second initialization voltage line VAL2 to the fourth source region S4 of the fourth semiconductor layer A4 of the fourth transistor T4 of the second pixel circuit PC2. The sixth connection pattern 1360 disposed in the third pixel circuit PC3 may connect the third initialization voltage line VAL3 to the fourth source region S4 of the fourth semiconductor layer A4 of the fourth transistor T4 of the third pixel circuit PC3.

The seventh connection pattern 1370 may be electrically connected to the first semiconductor pattern 1110 and the lower driving voltage line PL0 through a thirteenth contact hole CNT13 and a fourteenth contact hole CNT14 passing through at least one insulating layer. For example, one side of the seventh connection pattern 1370 may be connected to the first semiconductor pattern 1110 through the thirteenth contact hole CNT13, and the other side of the seventh connection pattern 1370 may be connected to the lower conductive pattern 1010 through the fourteenth contact hole CNT14. Specifically, the seventh connection pattern 1370 may electrically connect the lower conductive pattern 1010 to the fifth drain region D5 of the fifth semiconductor layer A5 of the fifth transistor T5 so that the driving voltage ELVDD may be applied to the fifth transistor T5.

Referring to FIGS. 15 and 20 together, a fifth insulating layer 115 may be disposed on the first source/drain layer SDL1, and a second source/drain layer SDL2 may be disposed on the fifth insulating layer 115. The second source/drain layer SDL2 may include a second common voltage line SS2, a third common voltage line SS3, a first upper driving voltage line PL11, a second upper driving voltage line PL12, a fourth initialization voltage line VAL4, a fifth conductive pattern 1410, a sixth conductive pattern 1420, a seventh conductive pattern 1430, an eighth conductive pattern 1440, a ninth conductive pattern 1450, and a tenth conductive pattern 1460.

The fifth insulating layer 115 may be a planarization layer and may include an organic insulating material. The fifth insulating layer 115 may be an organic insulating layer including an organic insulating material, such as acrylic, benzocyclobutene (BCB), polyimide, or hexamethyldisiloxane (HMDSO).

The second source/drain layer SDL2 may include a metal, an alloy, a conductive metal oxide, or a transparent conductive material. For example, the second source/drain layer SDL2 may include silver (Ag), an Ag-containing alloy, molybdenum (Mo), a Mo-containing alloy, aluminum (Al), an Al-containing alloy, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), ITO, or IZO. The second source/drain layer SDL2 may have a multilayer structure. For example, the second source/drain layer SDL2 may have a two-layer structure of Ti/Al or a three-layer structure of Ti/Al/Ti.

The third common voltage line SS3, the first upper driving voltage line PL11, the fifth conductive pattern 1410, and the sixth conductive pattern 1420 may be disposed to correspond to the first pixel circuit PC1. The second upper driving voltage line PL12, the seventh conductive pattern 1430, and the eighth conductive pattern 1440 may be disposed to correspond to the second pixel circuit PC2. The third common voltage line SS3 may be disposed across the second pixel circuit PC2 and the third pixel circuit PC3, and may be disposed in a symmetrical shape with respect to an imaginary line extending in the second direction (e.g., the y-axis direction). For example, the third common voltage line SS3 may include first and second portions disposed on opposite sides of a boundary between the second pixel circuit PC2 and the third pixel circuit PC3, the first and second portions having substantially corresponding shapes. The fourth initialization voltage line VAL4, the ninth conductive pattern 1450, and the tenth conductive pattern 1460 may be disposed to correspond to the third pixel circuit PC3.

The second common voltage line SS2 may extend in the second direction (e.g., the y-axis direction). The third common voltage line SS3 may have a symmetrical shape with respect to an imaginary line extending in the second direction (e.g., the y-axis direction). The imaginary line may be an imaginary line disposed between the second pixel circuit PC2 and the third pixel circuit PC3 to define the boundary therebetween, and the second common voltage line SS2 may be disposed on the imaginary line. For example, the third common voltage line SS3 may include first and second portions disposed on opposite sides of the boundary between the second pixel circuit PC2 and the third pixel circuit PC3, the first and second portions having substantially corresponding shapes, and the second common voltage line SS2 may be disposed along the boundary to extend between the first and second portions of the third common voltage line SS3. The second common voltage line SS2 may be electrically connected to the first common voltage line SS1 to be described below with reference to FIG. 16, and may form a horizontal-vertical mesh structure in the display area DA. For example, the first and second common voltage lines SS1 and SS2 may extend in intersecting directions and be electrically connected at a plurality of intersections to form a grid-type or lattice-type voltage distribution structure within the display area DA. In an embodiment, a first width W1 of the second common voltage line SS2 may be greater than a second width W2 of the third common voltage line SS3.

A first contact hole PCNT1 electrically connected to the first pad portion AEP1 of the first common voltage line SS1 to be described below with reference to FIG. 16 may be disposed on the second common voltage line SS2. The first contact hole PCNT1 may be formed to pass through at least one insulating layer (e.g., a sixth insulating layer 116 in FIG. 18) disposed between the second source/drain layer SDL2 of FIG. 15 and a pixel electrode layer PXL of FIG. 16. The first contact hole PCNT1 illustrated in FIG. 15 may refer to a portion where the second common voltage line SS2 is in contact with the first common voltage line (see SS1 of FIG. 16) through the first contact hole PCNT1. In an embodiment, the first contact hole PCNT1 may include a plurality of sub-contact holes SCNT.

The third common voltage line SS3 may extend in the second direction (e.g., the y-axis direction). The third common voltage line SS3 may be a vertical common voltage line disposed vertically in a plan view based on FIG. 14. The third common voltage line SS3 may be disposed along the second direction (e.g., the y-axis direction) and may extend to the peripheral area (see PA of FIG. 6). The third common voltage line SS3 may be electrically connected to the common voltage supply line 30 in the peripheral area (see PA of FIG. 6) so that the common voltage ELVSS may be applied to the third common voltage line SS3.

The fourth initialization voltage line VAL4 may extend approximately in the second direction (e.g., the y-axis direction). The fourth initialization voltage line VAL4 may be a vertical initialization voltage line disposed vertically in a plan view based on FIG. 14. The fourth initialization voltage line VAL4 may be disposed to correspond to the third pixel circuit PC3 and may be electrically connected to the sixth connection pattern (see 1360 of FIG. 13). The fourth initialization voltage line VAL4 may be electrically connected to the sixth connection pattern (see 1360 of FIG. 13) and may be configured to transmit an initialization voltage to the fourth transistor (see T4 of FIG. 7) of the third pixel circuit PC3. The fourth initialization voltage line VAL4 and the sixth connection pattern 1360 may be electrically connected through a first via contact hole VCNT1 passing through at least one insulating layer disposed to correspond to the third pixel circuit PC3.

The upper driving voltage line PL1 may extend approximately in the second direction (e.g., the y-axis direction). The upper driving voltage line PL1 may include a first upper driving voltage line PL11 disposed to correspond to the first pixel circuit PC1 and a second upper driving voltage line PL12 disposed to correspond to the second pixel circuit PC2. The upper driving voltage line PL1 may be electrically connected to the lower driving voltage line (see PL0 of FIG. 10). As such, because the lower driving voltage line PL0 and the upper driving voltage line PL1 are electrically connected to each other, the driving voltage line (see PL of FIG. 7) may be provided in a mesh form within the display area DA. For example, the lower driving voltage line PL0 may extend in a first direction within the display area DA, and the upper driving voltage line PL1 may extend in a second direction intersecting the first direction, such that the lower driving voltage line PL0 and the upper driving voltage line PL1 intersect at a plurality of locations to form a grid-like voltage distribution structure.

The first upper driving voltage line PL11 may be electrically connected to the seventh connection pattern (see 1370 of FIG. 14) disposed to correspond to the first pixel circuit PC1 through a second via contact hole VCNT2. The first upper driving voltage line PL11 may be electrically connected to the first hold electrode (see CEh1 of FIG. 7) of the first pixel circuit PC1 and the fifth semiconductor layer (see A5 of FIG. 13) of the fifth transistor (see T5 of FIG. 13). The seventh connection pattern 1370 may be electrically connected to the lower driving voltage line (see PL0 of FIG. 10), which is the horizontal driving voltage line, through the fourteenth contact hole CNT14 described above with reference to FIG. 14, and may be electrically connected to the first upper driving voltage line PL11, which is the vertical driving voltage line, through the second via contact hole VCNT2, so as to form a mesh structure within the display area DA. In some embodiments, the seventh connection pattern 1370 may be electrically connected to the first semiconductor pattern 1110 through the thirteenth contact hole CNT13 and electrically connected to the first upper driving voltage line PL11, which is the vertical driving voltage line, through the second via contact hole VCNT2 so that the driving voltage ELVDD may be transmitted to the fifth semiconductor layer (see A5 of FIG. 13) of the fifth transistor (see T5 of FIG. 13) of the first pixel circuit PC1.

The second upper driving voltage line PL12 may be electrically connected to the seventh connection pattern (see 1370 of FIG. 14) disposed to correspond to the second pixel circuit PC2 through a third via contact hole VCNT3. The second upper driving voltage line PL12 may be electrically connected to the first hold electrode (see CEh1 of FIG. 7) of the second pixel circuit PC2 and the fifth semiconductor layer (see A5 of FIG. 13) of the fifth transistor (see T5 of FIG. 13). The seventh connection pattern 1370 may be electrically connected to the lower driving voltage line PL0, which is the horizontal driving voltage line, through the fourteenth contact hole CNT14 described above with reference to FIG. 14, and may be electrically connected to the second upper driving voltage line PL12, which is the vertical driving voltage line, through the third via contact hole VCNT3, so as to form a mesh structure within the display area DA. In some embodiments, the seventh connection pattern 1370 may be electrically connected to the first semiconductor pattern 1110 through the thirteenth contact hole CNT13 and electrically connected to the second upper driving voltage line PL12, which is the vertical driving voltage line, through the third via contact hole VCNT3 so that the driving voltage ELVDD may be transmitted to the fifth semiconductor layer (see A5 of FIG. 13) of the fifth transistor (see T5 of FIG. 13) of the second pixel circuit PC2.

In a plan view based on FIG. 15, the second upper driving voltage line PL12 may have an approximate ladder shape. For example, the second upper driving voltage line PL12 may extend approximately in the second direction (e.g., the y-axis direction) and may include a plurality of openings PL1-OP. The plurality of openings PL1-OP provided in the second upper driving voltage line PL12 may be repeatedly provided with the seventh connection pattern 1370 and the eighth connection pattern 1380 therebetween. Out-gassing occurring in the insulating layer (e.g., the fifth insulating layer 115, etc.) including the organic material and disposed below the second upper driving voltage line PL12 may be effectively discharged to the outside through the plurality of openings PL1-OP provided in the second upper driving voltage line PL12. For example, the second upper driving voltage line PL12 may include a pair of longitudinal portions extending approximately in the second direction and a plurality of transverse portions connecting the pair of longitudinal portions, with the plurality of openings PL1-OP being defined between adjacent transverse portions, such that the second upper driving voltage line PL12 has an approximate ladder shape in a plan view.

The plurality of openings PL1-OP provided in the second upper driving voltage line PL12 may be disposed so as not to overlap an opening 117OP of a pixel defining layer 117 that exposes central portions of the first to third pixel electrodes PE1, PE2, and PE3 to be described below with reference to FIG. 18. Accordingly, unevenness of an upper surface profile of the pixel electrodes PE caused by the plurality of openings PL1-OP may be prevented, thereby suppressing degradation of light emission uniformity. In some embodiments, a second width W12 of the second upper driving voltage line PL12 extending in the first direction (e.g., the x-axis direction) may be greater than a first width W11 of the first upper driving voltage line PL11 extending in the first direction (e.g., the x-axis direction).

On the other hand, a fifth conductive pattern 1410 and a sixth conductive pattern 1420 may be disposed to correspond to the first pixel circuit PC1, a seventh conductive pattern 1430 and an eighth conductive pattern 1440 may be disposed to correspond to the second pixel circuit PC2, and a ninth conductive pattern 1450 and a tenth conductive pattern 1460 may be disposed to correspond to the third pixel circuit PC3. In a plan view, each of the fifth to tenth conductive patterns 1410 to 1460 may have an isolated shape for example, an island-shaped conductive pattern that is electrically isolated from other conductive patterns.

The fifth conductive pattern 1410, the seventh conductive pattern 1430, and the ninth conductive pattern 1450 may perform the same function in the first pixel circuit PC1, the second pixel circuit PC2, and the third pixel circuit PC3. In a plan view, each of the fifth conductive pattern 1410, the seventh conductive pattern 1430, and the ninth conductive pattern 1450 may have an approximately rectangular shape. Each of the fifth conductive pattern 1410, the seventh conductive pattern 1430, and the ninth conductive pattern 1450 may be electrically connected to the first connection pattern (see 1310 of FIG. 14) through a fourth via contact hole VCNT4 and may have a shape that covers the third connection pattern (see 1330 of FIG. 14). Because the fifth conductive pattern 1410, the seventh conductive pattern 1430, and the ninth conductive pattern 1450 shield the third connection pattern (see 1330 of FIG. 14) (or the first node electrode) connected to the storage capacitor (see Cst of FIG. 13), the image quality characteristics may be improved.

The sixth conductive pattern 1420, the eighth conductive pattern 1440, and the tenth conductive pattern 1460 may perform the same function in the first pixel circuit PC1, the second pixel circuit PC2, and the third pixel circuit PC3. The sixth conductive pattern 1420, the eighth conductive pattern 1440, and the tenth conductive pattern 1460 may electrically connect light-emitting diodes LED to pixel circuits PC, which are to be described below with reference to FIG. 18, through a fifth via contact hole VCNT5 passing through at least one insulating layer disposed on the second source/drain layer SDL2. For example, the first pixel electrode PE1 may be connected to the fourth transistor (see T4 of FIG. 13) and the sixth transistor (see T6 of FIG. 13) of the first pixel circuit PC1 through the sixth conductive pattern 1420 disposed on the first pixel circuit PC1. In some embodiments, the second pixel electrode PE2 may be connected to the fourth transistor (see T4 of FIG. 13) and the sixth transistor (see T6 of FIG. 13) of the second pixel circuit PC2 through the eighth conductive pattern 1440 disposed to correspond to the second pixel circuit PC2. In some embodiments, the third pixel electrode PE3 may be connected to the fourth transistor (see T4 of FIG. 13) and the sixth transistor (see T6 of FIG. 13) of the third pixel circuit PC3 through the tenth conductive pattern 1460 disposed to correspond to the third pixel circuit PC3.

Referring to FIGS. 16 and 20 together, a sixth insulating layer 116 may be disposed on the second source/drain layer SDL2, and a pixel electrode layer PXL may be disposed on the sixth insulating layer 116. The pixel electrode layer PXL may include a pixel electrode PE and an auxiliary electrode AE.

The sixth insulating layer 116 may be a planarization layer and may include an organic insulating material. The sixth insulating layer 116 may be an organic insulating layer including an organic insulating material, such as acrylic, benzocyclobutene (BCB), polyimide, or hexamethyldisiloxane (HMDSO).

The pixel electrode PE may include a first pixel electrode PE1 configured to emit light having a first wavelength, a second pixel electrode PE2 configured to emit light having a second wavelength, and a third pixel electrode PE3 configured to emit light having a third wavelength. In an embodiment, the first pixel electrode PE1 may be configured to emit first color light corresponding to a red color, the second pixel electrode PE2 may be configured to emit second color light corresponding to a green color, and the third pixel electrode PE3 may be configured to emit third color light corresponding to a blue color.

The pixel electrode PE may include a first pixel electrode PE1 electrically connected to the first pixel circuit PC1, a second pixel electrode PE2 electrically connected to the second pixel circuit PC2, and a third pixel electrode PE3 electrically connected to the third pixel circuit PC3. As such, the first to third pixel electrodes PE1, PE2, and PE3 may be electrically connected to the first to third pixel circuits PC1, PC2, and PC3, respectively, but the positions of the first to third pixel electrodes PE1, PE2, and PE3 are not necessarily located to correspond to the areas where the first to third pixel circuits PC1, PC2, and PC3 are disposed. In an embodiment, all or part of the first pixel electrode PE1 and the second pixel electrode PE2 may be disposed to correspond to the area where the first pixel circuit PC1 is disposed. The third pixel electrode PE3 may be disposed across the area where the second pixel circuit PC2 is disposed and the area where the third pixel circuit PC3 is disposed. The first pixel electrode PE1 and the second pixel electrode PE2 may be disposed in the same column (e.g., the first column) along the second direction (e.g., the y-axis direction) and may be alternately disposed. The third pixel electrodes PE3 may be disposed in the same column (e.g., the second column) adjacent to the first column.

The pixel electrode PE may be a (semi)transmissive electrode or a reflective electrode. For example, the pixel electrode PE may include a reflective layer and a transparent or semitransparent electrode layer disposed on the reflective layer. The reflective layer may include Ag, Mg, Al, Pt, Pd, Au, Ni, Nd, Ir, Cr, or any compound thereof. The transparent or semitransparent electrode layer may include at least one selected from ITO, IZO, zinc oxide (ZnOx: ZnO or ZnO₂), indium oxide (In₂O₃), indium gallium oxide (IGO), and aluminum zinc oxide (AZO). For example, the pixel electrode PE may have a three-layer structure of ITO/Ag/ITO.

The pixel electrode PE may be electrically connected to the pixel circuit PC disposed therebelow through the second contact hole PCNT2 located in a portion protruding to one side. The second contact hole PCNT2 may be formed to pass through at least one insulating layer (e.g., the sixth insulating layer 116 in FIG. 18) disposed between the pixel electrode layer PXL and the second source/drain layer SDL2.

The first pixel electrode PE1 may be electrically connected to the sixth conductive pattern (see 1420 of FIG. 15) disposed on the first pixel circuit PC1 through the second contact hole PCNT2. The second pixel electrode PE2 may be electrically connected to the eighth conductive pattern (see 1440 of FIG. 15) disposed on the second pixel circuit PC2 through the second contact hole PCNT2. The third pixel electrode PE3 may be electrically connected to the tenth conductive pattern (see 1460 of FIG. 15) disposed on the third pixel circuit PC3 through the second contact hole PCNT2.

The auxiliary electrode AE may extend approximately in the first direction (e.g., the x-axis direction). The auxiliary electrode AE may be disposed on the same layer as the pixel electrode PE and may include the same material as the material of the pixel electrode PE. The auxiliary electrode AE may be spaced apart from the pixel electrode PE.

The auxiliary electrode AE may include a plurality of pad portions AEP and a connection portion AEC connecting the plurality of pad portions AEP to each other. The plurality of pad portions AEP may be disposed in the same column (e.g., the second column) as the column in which the third pixel electrodes PE3 are disposed, and the third pixel electrodes PE3 and the plurality of pad portions AEP may be alternately disposed. The plurality of pad portions AEP may be connected to each other through the connection portion AEC extending in the first direction (e.g., the x-axis direction). The plurality of pad portions AEP disposed adjacent to each other may be integrally connected as a single body through the connection portion AEC.

The auxiliary electrode AE may be referred to as a first common voltage line SS1. That is, the auxiliary electrode AE may function as the first common voltage line SS1, and therefore, the common voltage ELVSS may be applied to the auxiliary electrode AE. In a plan view based on FIG. 16, the first common voltage line SS1 may be a horizontal common voltage line. The first common voltage line SS1, which is a horizontal common voltage line, may be electrically connected to the second common voltage line (see SS2 of FIG. 15), which is a vertical common voltage line, to form a mesh structure within the display area DA.

As the auxiliary electrode AE functions as the first common voltage line SS1, it may be understood that the first common voltage line SS1 includes the plurality of pad portions AEP and the connection portion AEC. For example, the auxiliary electrode AE may include a plurality of pad portions AEP arranged along the display area and a connection portion AEC electrically connecting the pad portions AEP to each other, such that the auxiliary electrode AE functions as the first common voltage line SS1. The first common voltage line SS1 may have a shape extending in the first direction (e.g., the x-axis direction).

The first common voltage line SS1 may be electrically connected to the second common voltage line SS2 through the first contact hole PCNT1 passing through at least one insulating layer (e.g., the sixth insulating layer 116 in FIG. 18). The second common voltage line SS2 may be directly connected to the first pad portion AEP1 of the first common voltage line SS1 through the first contact hole PCNT1.

The first contact hole PCNT1 may include a plurality of sub-contact holes SCNT. The plurality of sub-contact holes SCNT may be spaced apart from each other. Although FIG. 16 illustrates that five sub-contact holes SCNT are provided with respect to one first pad portion AEP1, the number of sub-contact holes SCNT may be adjusted as necessary. The number of sub-contact holes SCNT may be two or more, and may be five or more when necessary. In FIG. 16, the plurality of sub-contact holes SCNT may be spaced apart from each other in the second direction (e.g., the y-axis direction).

In an embodiment, the plurality of sub-contact holes SCNT may have the same size. In some embodiments, the size of each of the plurality of sub-contact holes SCNT may be equal to the size of the second contact hole PCNT2. In another embodiment, the sizes of the first to fifth via contact holes VCNT1 to VCNT5 described above with reference to FIG. 15 may be equal to each other, and the sizes of the plurality of sub-contact holes SCNT may be equal to the sizes of the first to fifth via contact holes VCNT1 to VCNT5 described above with reference to FIG. 15. The “size of the contact hole” may refer to the width of the contact hole defined by the insulating layer along the first direction (e.g., the x direction or the y direction) and the width of the contact hole defined by the insulating layer along the second direction (e.g., the y direction or the x direction) in a plan view. Therefore, the expression that “the sizes of the contact holes are equal to each other” may mean that the areas of the contact holes are equal to each other. For example, in the disclosure, the contact hole may have an approximately rectangular shape, or may have a rectangular shape with round corners. For example, the contact hole may have a rectangular shape with a ratio of about 4:3. The area of each of the plurality of sub-contact holes SCNT may be approximately equal to the area of the second contact hole PCNT2. Accordingly, the area of the first contact hole PCNT1 including the plurality of sub-contact holes SCNT may be greater than the area of the second contact hole PCNT2, for example, twice or more, or five times or more.

That is, the area of the first contact hole PCNT1 may increase as the first contact hole PCNT1 includes the plurality of sub-contact holes SCNT. In other words, this may mean that the contact area between the first common voltage line SS1 and the second common voltage line SS2 increases. As illustrated in FIG. 16, for example, the contact area in a case where five sub-contact holes SCNT are provided may increase five times, compared to a case where one contact hole is provided. Accordingly, because the contact area between the first common voltage line SS1 and the second common voltage line SS2 increases, the increase in contact resistance may be reduced, and thus, the voltage drop (IR drop) may be minimized. For example, the contact resistance may include resistance at an interface between the first common voltage line SS1 and the second common voltage line SS2 through one or more contact holes formed in an insulating layer.

Referring to FIGS. 17 and 20 together, an upper insulating layer UIL may be disposed on the first pixel electrode PE1, the second pixel electrode PE2, and the third pixel electrode PE3. The upper insulating layer UIL may include a pixel defining layer 117 and a spacer layer 119, which are to be described with reference to FIG. 18. The upper insulating layer UIL may have an opening 117OP exposing central portions of the first pixel electrode PE1, the second pixel electrode PE2, and the third pixel electrode PE3. The opening 117OP may define emission areas EA1, EA2, and EA3 of the first pixel electrode PE1, the second pixel electrode PE2, and the third pixel electrode PE3. A first emission layer EL1, a second emission layer EL2, and a third emission layer EL3 may be respectively disposed on the first pixel electrode PE1, the second pixel electrode PE2, and the third pixel electrode PE3 exposed through the opening 117OP.

Referring to FIG. 18, a buffer layer 101, a first insulating layer 111, a second insulating layer 112, a third insulating layer 113, a fourth insulating layer 114, a fifth insulating layer 115, and a sixth insulating layer 116 may be disposed on a substrate 100, and a portion of the first bottom metal layer BML1, the second bottom metal layer BML2, the semiconductor layer ACT, the gate layer GAT, the first source/drain layer SDL1, and the second source/drain layer SDL2 described above with reference to FIGS. 10 to 17 may be disposed therebetween.

The second common voltage line SS2 may be disposed on the fifth insulating layer 115, and the sixth insulating layer 116 may be disposed on the second common voltage line SS2. The first pad portion AEP1 of the first common voltage line SS1 may be disposed on the sixth insulating layer 116. The first contact hole PCNT1 may include the plurality of sub-contact holes SCNT, and the plurality of sub-contact holes SCNT may pass through the sixth insulating layer 116. The plurality of sub-contact holes SCNT may be spaced apart from each other in the second direction (e.g., the y-axis direction).

The upper insulating layer UIL may be disposed on the first common voltage line SS1, and an opposite electrode 230 may be disposed on the upper insulating layer UIL. FIG. 18 illustrates that the opposite electrode 230 is disposed directly on the upper insulating layer UIL, but as an example, first and second functional layers 221 and 223 to be described below with reference to FIG. 20 may be further disposed between the upper insulating layer UIL and the opposite electrode 230.

FIG. 19 corresponds to a modification of FIG. 16.

Referring to FIG. 19, the first contact hole PCNT1 may have a structure extending in the second direction (e.g., the y-axis direction). The first contact hole PCNT1 may have a first width w1 along the first direction (e.g., the x-axis direction) and a second width w2 along the second direction (e.g., the y-axis direction), and the second width w2 may be at least twice greater than the first width w1. For example, the first contact hole PCNT1 may have an approximately rectangular shape. The area of the first contact hole PCNT1 may be greater than the area of the first contact hole PCNT1 described above with reference to FIG. 16, and may be greater than the area of the second contact hole PCNT2 illustrated in FIG. 19.

As the first contact hole PCNT1 has a shape that extends in one direction, the area of the first contact hole PCNT1 may increase, thereby increasing a contact area between the first common voltage line SS1 and the second common voltage line SS2. Accordingly, as the contact area between the first common voltage line SS1 and the second common voltage line SS2 increases, contact resistance may be reduced, and thus, a voltage drop (IR drop) may be minimized.

Referring again to FIG. 20, a light-emitting diode LED may be disposed on the sixth insulating layer 116. The light-emitting diode LED may include a pixel electrode 210, an intermediate layer 220 including an emission layer 222, and an opposite electrode 230. The pixel electrode 210 illustrated in FIG. 20 may be one of the first pixel electrode PE1, the second pixel electrode PE2, and the third pixel electrode PE3, which have been described above with reference to FIG. 17.

The pixel defining layer 117 may be disposed on the pixel electrode 210. For example, the patterned pixel electrode 210 may be disposed on the sixth insulating layer 116, and the pixel defining layer 117 may be disposed on the sixth insulating layer 116 while covering at least a portion of the pixel electrode 210. Because the pixel defining layer 117 covers the edge of the pixel electrode 210, the pixel defining layer 117 may prevent an electric arc or similar phenomenon from occurring at the edge of the pixel electrode 210 by increasing the distance between the pixel electrode 210 and the opposite electrode 230 on the pixel electrode 210. The pixel defining layer 117 may have the opening 117OP to expose the central portion of the pixel electrode 210. The central portion of the pixel electrode PE exposed through the opening 117OP of the pixel defining layer 117 may be defined as an emission area EA.

The pixel defining layer 117 may include at least one organic insulating material selected from polyimide, polyamide, acrylic resin, BCB, and phenol resin and may be formed by spin coating or the like. In another embodiment, the pixel defining layer 117 may include an organic insulating material including a light-blocking material. Alternatively, the pixel defining layer 117 may include a polyimide (PI)-based binder and a pigment in which red, green, and blue are mixed. Alternatively, the pixel defining layer 117 may include a mixture of a cardo-based binder resin, a lactam black pigment, and a blue pigment. Alternatively, the pixel defining layer 117 may include carbon black. Accordingly, the pixel defining layer 117 may improve the contrast of the display device 10 by including a colored material.

The spacer layer 119 may be disposed on the pixel defining layer 117. The spacer layer 119 may include a material that is different from a material of the pixel defining layer 117. For example, the pixel defining layer 117 may include a negative photosensitive material and the spacer layer 119 may include a positive photosensitive material. As such, the pixel defining layer 117 and the spacer layer 119 may include different materials. The pixel defining layer 117 and the spacer layer 119 may be formed through separate mask processes. In another embodiment, the spacer layer 119 may include the same material as the material of the pixel defining layer 117 and may be formed together with the pixel defining layer 117 through the same mask process (e.g., a half-tone mask process).

At least a portion of the intermediate layer 220 including the emission layer 222 of the light-emitting diode LED may be disposed within the opening 117OP formed in the pixel defining layer 117. The intermediate layer 220 may include the emission layer 222. The emission layer 222 may include a high molecular weight organic material or a low molecular weight organic material that emits light of a certain color. The emission layer 222 may include a material that emits red light, green light, or blue light, depending on the light-emitting diode LED.

A functional layer may be further included below and/or above the emission layer 222. For example, a first functional layer 221 may be further included between the pixel electrode 210 and the emission layer 222, and a second functional layer 223 may be further included between the emission layer 222 and the opposite electrode 230 to be described below. The first functional layer 221 may include a hole transport layer (HTL) and/or a hole injection layer (HIL). The second functional layer 223 may include an electron transport layer (ETL) and/or an electron injection layer (EIL).

The emission layer 222 may have a shape patterned to correspond to the pixel electrode 210. Layers other than the emission layer 222 included in the intermediate layer 220 may be variously modified. For example, the layers may be integrally formed across the pixel electrodes 210.

The opposite electrode 230 may be a transmissive electrode or a reflective electrode. For example, the opposite electrode 230 may be a transparent or semitransparent electrode and may include a metal thin-film having a low work function and including Li, Ca, Al, Ag, Mg, or any compound thereof (e.g., LiF). In some embodiments, the opposite electrode 230 may further include a transparent conductive oxide (TCO) layer, such as ITO, IZO, ZnO, ZnO₂, or In₂O₃, disposed on the metal thin-film.

The opposite electrode 230 may be integrally formed as a single body across the entire display area DA to cover the display area DA, and may be disposed on the intermediate layer 220 and the pixel defining layer 117. For example, the plurality of pixel electrodes 210 may be respectively disposed to correspond to the plurality of light-emitting diodes LED, and the opposite electrodes 230 may be integrally formed to correspond to the plurality of light-emitting diodes LED. The plurality of light-emitting diodes LED may share the opposite electrode 230, and a stacked structure of the pixel electrode 210, the intermediate layer 220, and the opposite electrode 230 may correspond to the light-emitting diode LED.

When necessary, an encapsulation layer may be disposed on the light-emitting diode LED. The encapsulation layer may include a first inorganic encapsulation layer, a second inorganic encapsulation layer, and an organic encapsulation layer therebetween.

FIG. 21 is a cross-sectional view schematically illustrating a portion of a display device according to an embodiment. FIG. 21 illustrates a modified example of the structure shown in FIG. 20.

Referring to FIG. 21, the structure of FIG. 21 is substantially the same as the structure of FIG. 20 with respect to the pixel circuit PC, except for the structure of the light-emitting diode LED and the spacer layer 119 disposed on the light-emitting diode LED. Hereinafter, differences in the light-emitting diode LED and the spacer layer 119 are mainly described.

In an embodiment, the light-emitting diode LED may be provided as a tandem-type light-emitting diode LED including a plurality of vertically stacked emission layers 222a and 222b.

The intermediate layer 220 may include a first stack ST1 including a first emission layer 222a and first and second functional layers 221 and 223 disposed with the first emission layer 222a therebetween, a second stack ST2 including a second emission layer 222b and first and second functional layers 221′ and 223′ disposed with the second emission layer 222b therebetween, and a charge generation layer 224 disposed between the first stack ST1 and the second stack ST2. In the first stack ST1 and the second stack ST2, the first and second functional layers 221 and 223 and the first and second functional layers 221′ and 223′ may all be provided, or one or more of these functional layers may be omitted.

The charge generation layer 224 may include a negative charge generation layer and a positive charge generation layer. In the case of the tandem-type light-emitting diode LED including a plurality of emission layers formed by a negative charge generation layer and a positive charge generation layer, the light emission efficiency may be further improved.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

A groove 119G may be disposed on the upper portion of the spacer layer 119. In a plan view, the groove 119G may be disposed to surround at least a portion of the emission area EA of the pixel PX. When the tandem-type light-emitting diode LED is provided as described above, the groove 119G may be configured such that at least a portion of the charge generation layer 224 is disconnected by the step difference of the groove 119G. The charge generation layer 224 may be provided discontinuously in at least some areas by the step difference of the groove 119G disposed on the spacer layer 119. As the groove 119G is disposed to surround at least a portion of the emission area EA of the pixel PX, the charge generation layer 224 may be provided discontinuously to surround at least a portion of the emission area EA of the pixel PX. Accordingly, current leakage occurring between the pixels PX may be prevented, and thus, light mixing between the pixels PX may be minimized.

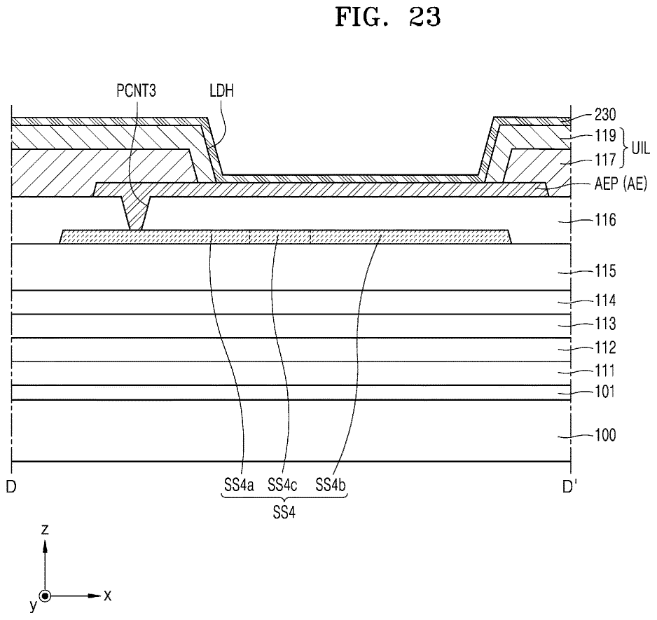

FIG. 22 is a cross-sectional view schematically illustrating a portion of a display device according to an embodiment. FIG. 22 may correspond to the enlarged structure of region C of FIG. 8. FIG. 23 is a cross-sectional view schematically illustrating a cross-section taken along line D-D′ of FIG. 22.

Referring to FIGS. 22 and 23, the display device 10 may have a structure in which a first pixel PX1, a second pixel PX2, and a third pixel PX3 sequentially disposed in the first direction (e.g., the x-axis direction) are repeatedly disposed in the first direction (e.g., the x-axis direction) and the second direction (e.g., the y-axis direction). For example, a first pixel circuit PC1 of the first pixel PX1 may be referred to as a first color (e.g., red) pixel circuit, a second pixel circuit PC2 of the second pixel PX2 may be referred to as a second color (e.g., green) pixel circuit, and a third pixel circuit PC3 of the third pixel PX3 may be referred to as a third color (e.g., blue) pixel circuit.

The areas where the first pixel PX1, the second pixel PX2, and the third pixel PX3 are disposed may be areas where the first pixel circuit PC1 included in the first pixel PX1, the second pixel circuit PC2 included in the second pixel PX2, and the third pixel circuit PC3 included in the third pixel PX3 are disposed. However, light-emitting diodes included in the first to third pixels PX1, PX2, and PX3 do not have to be disposed within the areas indicated by the first to third pixel circuits PC1, PC2, and PC3. For example, as illustrated in FIG. 22, a first pixel electrode PE1 included in the first pixel PX1 may be disposed across the area indicated by the first pixel circuit PC1 and extend in the −y direction, a second pixel electrode PE2 included in the second pixel PX2 may be disposed in the +y direction from the first pixel electrode PE1 and disposed in the area indicated by the first pixel circuit PC1, and a third pixel electrode PE3 included in the third pixel PX3 may be disposed across the area indicated by the second pixel circuit PC2 and the area indicated by the third pixel circuit PC3 and extend in the −y direction. For example, the first pixel electrode PE1 and the second pixel electrode PE2 may be disposed in the same column (e.g., the first column) along the second direction (e.g., the y-axis direction) and may be alternately disposed. The third pixel electrodes PE3 may be disposed in the column (e.g., the second column) adjacent to the column in which the first pixel electrodes PE1 and the second pixel electrodes PE2 are disposed.

On the other hand, the plurality of pad portions (see AEP of FIG. 8) may be disposed between the third pixel electrodes PE3 disposed in the second direction (e.g., the y-axis direction). For example, the pad portions AEP may be disposed in the same column (e.g., the second column) as the third pixel electrodes PE3, and the pad portions AEP and the third pixel electrodes PE3 may be alternately disposed. As described above with reference to FIG. 8, the plurality of pad portions AEP may include a second pad portion AEP2. FIGS. 22 and 23 illustrate the second pad portion AEP2.

In an embodiment, an upper insulating layer UIL may be disposed on the second pad portion AEP2. The upper insulating layer UIL may include a pixel defining layer 117 and a spacer layer 119. The upper insulating layer UIL may include both the pixel defining layer 117 and the spacer layer 119, or may include only one of the pixel defining layer 117 and the spacer layer 119.

The second pad portion AEP2 may include a main portion AEP2m having an approximately circular shape and a protruding portion AEP2p protruding in at least one direction. Although the second pad portion AEP2 is described with reference to FIG. 22, the description thereof may be applicable to the structure of the first pad portion AEP1.

The upper insulating layer UIL may include an opening LDH exposing the central portion of the second pad portion AEP2. The opening LDH may be disposed in the main portion AEP2m of the second pad portion AEP2. As illustrated in FIG. 23, the opposite electrode 230 disposed on the upper insulating layer UIL may be in direct contact with the second pad portion AEP2 through the opening LDH. For example, the opening LDH defined in the upper insulating layer UIL may be formed through a laser drilling process. For example, the opening LDH defined in the upper insulating layer UIL may be a laser drilling hole. According to the laser drilling process, after a cathode (e.g., the opposite electrode 230) is formed, a laser is irradiated onto the cathode to melt and remove an insulating layer (e.g., the upper insulating layer UIL) disposed between the cathode and a laser drilling pad (e.g., the second pad portion AEP2) so as to electrically connect the cathode to the laser drilling pad. The opening LDH may be formed in an area where the upper insulating layer UIL has been removed through the laser drilling process. For example, the opening LDH may be provided so that an end portion 117e of the pixel defining layer 117 is covered by an end portion 119e of the spacer layer 119.

The second pad portion AEP2 may include the protruding portion AEP2p protruding from one side in at least one direction. For example, based on the plan view illustrated in FIG. 22, the protruding portion AEP2p may extend approximately in the-x direction. A third contact hole PCNT3 may be disposed in the protruding portion AEP2p. The third contact hole PCNT3 may be connected to a fourth common voltage line SS4 disposed below the second pad portion AEP2. As the second pad portion AEP2 is electrically connected to the fourth common voltage line SS4 through the third contact hole PCNT3, a common voltage ELVSS may be applied to the second pad portion AEP2.

Because the third contact hole PCNT3 is provided to correspond to the protruding portion AEP2p, the third contact hole PCNT3 and the opening LDH may be disposed so as not to overlap each other. In a plan view, the third contact hole PCNT3 and the opening LDH may be spaced apart from each other.

As a comparative example, when the third contact hole PCNT3 is located below the main portion AEP2m of the second pad portion AEP2 and disposed to overlap the opening LDH, the upper surface of the main portion AEP2m of the second pad portion AEP2 may become non-flat due to the third contact hole PCNT3. In such a case, a measurement error may occur during the laser drilling process when detecting a position of the opening LDH, which serves as a laser drilling hole. Therefore, in the second pad portion AEP2, the third contact hole PCNT3 and the opening LDH may be provided so as not to overlap each other.

In a plan view, the area of the opening LDH may be greater than the area of the third contact hole PCNT3.

On the other hand, the fourth common voltage line SS4 may be disposed below the second pad portion AEP2. In a plan view, the fourth common voltage line SS4 may extend approximately in the second direction (e.g., the y-axis direction). At least a portion of the fourth common voltage line SS4 may overlap the second pad portion AEP2. In the pixel circuit area including the second pad portion AEP2, except for the structure of the fourth common voltage line SS4, the lines disposed on the same layer as the fourth common voltage line SS4, for example, the first upper driving voltage line PL11, the third common voltage line SS3, and the fourth initialization voltage line VAL4, may be similar to those described above with reference to FIG. 15. Therefore, the following focuses on differences relating to the fourth common voltage line SS4.

In the pixel circuit area including the second pad portion AEP2, the fourth common voltage line SS4 may include a first sub-common voltage line SS4a and a second sub-common voltage line SS4b. In a plan view, the first sub-common voltage line SS4a and the second sub-common voltage line SS4b may be disposed approximately parallel to each other. A connection portion SS4c connecting the first sub-common voltage line SS4a to the second sub-common voltage line SS4b may be disposed between the first sub-common voltage line SS4a and the second sub-common voltage line SS4b. Accordingly, the first sub-common voltage line SS4a and the second sub-common voltage line SS4b may be integrally provided as a single body to form one wide common voltage line. The fourth common voltage line SS4 may be provided a single line within a pixel unit structure, such as the pixel unit structure described above with reference to FIG. 8, etc. As such, because the fourth common voltage line SS4 has a relatively wider width (area) than other common voltage lines described above with reference to FIGS. 9 and 15, for example, the first to third common voltage lines SS1, SS2, and SS3, line resistance may be reduced and voltage drop may be effectively reduced when transmitting the common voltage ELVSS.

The connection portion SS4c connecting the first sub-common voltage line SS4a to the second sub-common voltage line SS4b may overlap the second pad portion AEP2. For example, as illustrated in FIGS. 20 and 21, the connection portion SS4c may overlap the second pad portion AEP2 on the entire surface. For example, the connection portion SS4c may be completely covered by the second pad portion AEP2.

According to one or more embodiments, a display device and an electronic device, which have improved power consumption and provide high-quality images, may be provided.

It should be understood that the embodiments described herein are provided for purposes of illustration and description and are not intended to be limiting. Features or aspects described in connection with one embodiment may be applied to other embodiments as appropriate. While one or more embodiments have been described with reference to the figures, it will be understood by those of ordinary skill in the art that various changes in form and details may be made therein without departing from the spirit and scope of the disclosure.

What is claimed is:

1. A display device comprising:
a substrate comprising a display area including a first pixel having a first pixel electrode and a second pixel having a second pixel electrode, and a peripheral area disposed outside the display area;
a first common voltage line having a plurality of pad portions extending in a first direction in the display area and spaced apart from each other in the first direction;
a second common voltage line extending in a second direction crossing the first direction so as to overlap the second pixel electrode in the display area; and
an insulating layer disposed between the first common voltage line and the second common voltage line,
wherein the second common voltage line is electrically connected to a corresponding pad portion of the plurality of pad portions of the first common voltage line through a first contact hole passing through the insulating layer in an area overlapping the corresponding pad portion.

2. The display device of claim 1, wherein the first contact hole comprises a plurality of sub-contact holes spaced apart from each other.

3. The display device of claim 1, wherein the first contact hole has a first width along the first direction and a second width along the second direction, and
the second width is greater than the first width.

4. The display device of claim 1, further comprising:
a first conductive pattern including a same material as a material of the first common voltage line; and
a second conductive pattern including a same material as a material of the second common voltage line,
wherein the insulating layer further comprises a second contact hole, and
the first conductive pattern is electrically connected to the second conductive pattern through a second contact hole in an area overlapping the second conductive pattern.

5. The display device of claim 4, wherein an area of the first contact hole is greater than an area of the second contact hole.

6. The display device of claim 4, wherein an area of the first contact hole is at least twice an area of the second contact hole.

7. The display device of claim 4, wherein the first contact hole comprises a plurality of sub-contact holes spaced apart from each other, and
an area of one of the plurality of sub-contact holes is equal to an area of the second contact hole.

8. The display device of claim 4, wherein the first conductive pattern comprises the first pixel electrode.

9. The display device of claim 1, wherein the first pixel electrode and the first common voltage line comprise a same material.

10. The display device of claim 1, further comprising a third common voltage line extending in the second direction so as to overlap the first pixel electrode in the display area.

11. The display device of claim 10, wherein the third common voltage line includes a same material as a material of the second common voltage line.

12. The display device of claim 1, wherein the second pixel is provided in plurality, and
the plurality of pad portions are alternately disposed with a plurality of second pixel electrodes disposed in the second direction.

13. The display device of claim 1, wherein the second pixel is configured to emit light having a blue wavelength.

14. The display device of claim 1, further comprising a third pixel spaced apart from the first pixel in the second direction and having a third pixel electrode,
wherein the first common voltage line is disposed to pass between the first pixel electrode and the third pixel electrode.

15. The display device of claim 1, wherein the plurality of pad portions comprise a first pad portion and a second pad portion, and
a first contact hole disposed to correspond to the first pad portion is disposed in a central portion of the first pad portion.

16. The display device of claim 15, wherein the second pad portion comprises a protruding portion protruding in at least one direction, and
a third contact hole disposed to correspond to the second pad portion is disposed in the protruding portion.

17. The display device of claim 15, wherein at least one insulating layer is further disposed on the plurality of pad portions, and
the at least one insulating layer has an opening exposing a central portion of the second pad portion.

18. The display device of claim 15, further comprising, in a plan view, a fourth common voltage line at least partially overlapping an opening of an insulating layer disposed on the second pad portion and extending in the second direction,
wherein the fourth common voltage line comprises a first sub-common voltage line and a second sub-common voltage line, and
the first sub-common voltage line and the second sub-common voltage line have a connection portion where the first sub-common voltage line and the second sub-common voltage line are connected to each other in a partial area.

19. The display device of claim 1, further comprising a third common voltage line extending in the second direction,
wherein the first pixel comprises:
a first light-emitting element comprising the first pixel electrode; and
a first pixel circuit electrically connected to the first light-emitting element,
wherein the first pixel circuit comprises:
a thin-film transistor comprising a semiconductor layer, a gate electrode at least partially overlapping the semiconductor layer, and a first conductive layer disposed on the gate electrode and electrically connected to the semiconductor layer; and
a second conductive layer disposed on the thin-film transistor,
wherein each of the second common voltage line and the third common voltage line includes a same material as a material of the second conductive layer.

20. An electronic device comprising:
a display device; and
a housing accommodating the display device,
wherein the display device comprises:
a substrate comprising a display area including a first pixel having a first pixel electrode and a second pixel having a second pixel electrode, and a peripheral area disposed outside the display area;
a first common voltage line having a plurality of pad portions extending in a first direction in the display area and spaced apart from each other in the first direction;
a second common voltage line extending in a second direction crossing the first direction so as to overlap the second pixel electrode in the display area; and
an insulating layer disposed between the first common voltage line and the second common voltage line,
wherein the second common voltage line is electrically connected to a corresponding pad portion of the plurality of pad portions of the first common voltage line through a first contact hole passing through the insulating layer in an area overlapping the corresponding pad portion.
